(19) United States
(12) Patent Application Publication
(10) Pub. No.: US 2025/0318251 A1
(43) Pub. Date: Oct. 9, 2025

(54) Trench Semiconductor Structure and Manufacturing Method Thereof

(71) Applicant: Diodes Incorporated, Plano, TX (US)

(72) Inventors: Ta-Chuan Kuo, New Taipei City (TW); Chiao-Shun Chuang, New Taipei City (TW)

(21) Appl. No.: 19/083,365

(22) Filed: Mar. 18, 2025

(30) Foreign Application Priority Data
Apr. 3, 2024 (CN) 202410396793.7

(51) Int. Cl. H10D 84/00; H10D 84/01

(52) U.S. Cl. CPC H10D 84/146; H10D 84/0109

(57) ABSTRACT

A trench semiconductor structure includes a semiconductor material layer having a first surface and a second surface opposite to the first surface. A first trench structure extends from the first surface toward the second surface, and includes a first electrode, a second electrode above the first electrode, and a first oxide layer surrounding and separating the first electrode and the second electrode. A second trench structure extends from the first surface toward the second surface, and includes a first gate, a third electrode below the first gate, and a second oxide layer surrounding and separating the third electrode and the first gate. A first doped region is provided in the semiconductor material layer, away from the first surface, and between the first trench structure and the second trench structure. A second doped region is provided between the first surface and the first doped region.

### CROSS-REFERENCE TO RELATED APPLICATIONS

This patent application claims priority to Chinese Patent Application No. 202410396793.7, filed on Apr. 3, 2024 and entitled “TRENCH SEMICONDUCTOR STRUCTURE AND MANUFACTURING METHOD,” which is hereby incorporated by reference herein as if reproduced in its entirety.

### TECHNICAL FIELD

The present disclosure relates generally to the field of semiconductors, and more particularly, to semiconductor structures and methods of manufacturing the same. A particular embodiment provides a trench metal oxide semiconductor (MOS) structure including a rectifier and a method of manufacturing the same.

### BACKGROUND

Modern power circuits require rectifiers that provide high power, low power loss and fast switching. Integrating a super-barrier-rectifier (SBR) with a shielded gate trench metal oxide semiconductor field effect transistor (SGT MOSFET) can minimize the forward voltage of the body diode, thereby reducing power loss.

Known integration methods involve designing a dedicated trench structure to set the SBR gate such that the trench for setting the SBR is adjacent to the trench for setting the SGT MOSFET. However, a trade-off has to be made between the performance of the SGT MOSFET and the SBR, which can be achieved by adjusting the lengths of the channels of the SGT MOSFET and the SBR. In terms of the correlation between the two channels mentioned above, the channel length of the SBR is often smaller than the channel length of the SGT MOSFET. According to current manufacturing methods, attempting to reduce the RDS(on) of the SGT MOSFET by shortening the channel length of the SGT MOSFET may cause the channel length of the SBR to become too short, resulting in increased leakage current and reduced device breakdown voltage (BVDSS), which has a negative impact on the overall performance and system efficiency of the overall diode. In addition, configuration and concentration of relevant doped regions need to be taken into consideration in adjusting the channel lengths, to avoid situations such as generation of high electric fields near the top surface under high bias due to doping imbalance, which result in unnecessary and uncontrollable high leakage current.

The present manufacturing methods of trench semiconductor structures lack flexibility of adjusting channel lengths. Therefore, the existing technology needs to be further improved in order to obtain more ideal high power and low loss, to improve device performance.

### SUMMARY

Embodiment of the present disclosure relate to a trench semiconductor structure. The trench semiconductor structure includes: a semiconductor material layer having a first surface and a second surface opposite to the first surface, wherein the semiconductor material layer has a first conductivity type; a first trench structure extending from the first surface toward the second surface, wherein the first trench structure includes a first electrode, a second electrode located above the first electrode, and a first oxide layer surrounding the first electrode and the second electrode and separating them from each other; a second trench structure extending from the first surface toward the second surface and disposed adjacent to the first trench structure, wherein the second trench structure includes a first gate, a third electrode located below the first gate, and a second oxide layer surrounding the third electrode and the first gate and separating them from each other; a first doped region located in the semiconductor material layer, away from the first surface, and between the first trench structure and the second trench structure, wherein the first doped region has a second conductivity type, and a first boundary defining the first doped region in the semiconductor material layer includes a first portion and a second portion; and a second doped region located between the first surface and the first doped region, wherein the second doped region has the first conductivity type. The first portion of the first boundary is adjacent to the first trench structure, the second portion of the first boundary line is adjacent to the second trench structure, and a distance between the first portion and the first surface is different from a distance between the second portion and the first surface.

Embodiment of the present disclosure also relate to a trench semiconductor structure. The trench semiconductor structure includes: a semiconductor material layer having a first surface and a second surface opposite to the first surface, wherein the semiconductor material layer has a first conductivity type; a first trench structure extending from the first surface toward the second surface, wherein the first trench structure includes a first electrode, a second electrode located above the first electrode, and a first oxide layer surrounding the first electrode and the second electrode and separating them from each other; a second trench structure extending from the first surface toward the second surface and disposed adjacent to the first trench structure, wherein the second trench structure includes a first gate, a third electrode located below the first gate, and a second oxide layer surrounding the third electrode and the first gate and separating them from each other; a first doped region located in the semiconductor material layer, away from the first surface, and between the first trench structure and the second trench structure, wherein the first doped region has a second conductivity type and contacts the first oxide layer; and a second doped region located in the semiconductor material layer, away from the first surface, and between the first doped region and the second trench structure, wherein the second doped region has a second conductivity type and contacts the second oxide layer, wherein a length of the first doped region is different from a length of the second doped region.

Embodiments of the present disclosure relate to a method for manufacturing a trench semiconductor structure. The method includes: forming a first trench and a second trench in a semiconductor material layer, the semiconductor material layer having a first conductivity type, the first trench and the second trench extending from a first surface toward a second surface; forming a first electrode and a first oxide layer in the first trench, the first oxide layer surrounding the first electrode and conforming to the first trench; forming a third electrode, a first gate, and a second oxide layer in the second trench, the second oxide layer surrounding the third electrode and the first gate and conforming to the second trench, and the third electrode, the first gate and the second oxide layer forming a second trench structure; forming a first doped region in the semiconductor material layer, away from the first surface, and located between a first trench structure and the second trench structure, wherein the first doped region is in contact with the first oxide layer; forming a second electrode in the first trench, wherein at least a portion of the first oxide layer is between the second electrode and the first doped region, and the first electrode, the second electrode and the first oxide layer form a first trench structure; and forming a second doped region in the semiconductor material layer, away from the first surface, and between the first doped region and the second trench structure, wherein the second doped region has a second conductivity type and is in contact with the first doped region and the second oxide layer, and wherein a distance between the bottom surface of the first doped region and the first surface is different from a distance between the bottom surface of the second doped region and the first surface.

In accordance with one aspect of the present disclosure, a trench semiconductor structure is provided that includes: a semiconductor material layer of a first conductivity type, the semiconductor material layer having a first surface and a second surface opposite to the first surface; a first trench structure extending from the first surface toward the second surface, wherein the first trench structure comprises a first electrode, a second electrode located above the first electrode, and a first oxide layer surrounding and separating the first electrode and the second electrode; a second trench structure extending from the first surface toward the second surface, wherein the second trench structure comprises a first gate, a third electrode located below the first gate, and a second oxide layer surrounding and separating the third electrode and the first gate; a first doped region of a second conductivity type in the semiconductor material layer, away from the first surface, and between the first trench structure and the second trench structure, wherein the first doped region has a first boundary between the first doped region and the semiconductor material layer, and the first boundary includes a first portion and a second portion; and a second doped region of the first conductivity type between the first surface and the first doped region.

In accordance with another aspect of the present disclosure, a trench semiconductor structure is provided that includes: a semiconductor material layer of a first conductivity type having a first surface and a second surface opposite to the first surface; a first trench structure extending from the first surface toward the second surface, wherein the first trench structure includes a first electrode, a second electrode located above the first electrode, and a first oxide layer surrounding and separating the first electrode and the second electrode; a second trench structure extending from the first surface toward the second surface, wherein the second trench structure comprises a first gate, a third electrode located below the first gate, and a second oxide layer surrounding and separating the third electrode and the first gate; a first doped region of a second conductivity type, located in the semiconductor material layer in contact with the first oxide layer, away from the first surface, and between the first trench structure and the second trench structure; and a second doped region of the second conductivity type, located in the semiconductor material layer, away from the first surface, between the first doped region and the second trench structure, and in contact with the second oxide layer; and wherein a length of the first doped region is different from a length of the second doped region.

In accordance with yet another aspect of the present disclosure, a method of manufacturing a trench semiconductor structure is provided that includes: forming a first trench and a second trench in a semiconductor material layer of a first conductivity type, wherein the first trench and the second trench extend from a first surface of the semiconductor material layer toward a second surface of the semiconductor material layer; forming, in the first trench, a first electrode, a second electrode, and a first oxide layer surrounding and separating the first electrode and the a second electrode, the first electrode, the second electrode and the first oxide layer forming a first trench structure; forming, in the second trench, a third electrode, a first gate, and a second oxide layer surrounding and separating the third electrode and the first gate, the third electrode, the first gate and the second oxide layer forming a second trench structure; forming a first doped region in the semiconductor material layer, away from the first surface, and between the first trench and the second trench, wherein at least a portion of the first oxide layer is between the second electrode and the first doped region, and the first doped region is in contact with the first oxide layer; and forming a second doped region in the semiconductor material layer, away from the first surface, and between the first doped region and the second trench, wherein the second doped region is in contact with the first doped region and the second oxide layer; and wherein a distance between a bottom surface of the first doped region and the first surface is different from a distance between a bottom surface of the second doped region and the first surface.

### BRIEF DESCRIPTION OF THE DRAWINGS

Aspects of several embodiments of the present disclosure may be best understood when the following detailed description is read in conjunction with the accompanying drawings. It should be noted that various structures may not be drawn to scale. In fact, the dimensions of various structures may be arbitrarily enlarged or reduced for clarity of discussion.

FIG. 1 is a cross-sectional view of an example trench semiconductor structure according to embodiments of the present disclosure;

FIG. 2 is a cross-sectional view of another example trench semiconductor structure according to embodiments of the present disclosure;

FIG. 3 is a cross-sectional view of yet another example trench semiconductor structure according to embodiments of the present disclosure;

FIG. 4 is a cross-sectional view of yet another example trench semiconductor structure according to embodiments of the present disclosure;

FIG. 5 is a cross-sectional view of yet another example trench semiconductor structure according to embodiments of the present disclosure;

FIG. 6 is a cross-sectional view of yet another example trench semiconductor structure according to embodiments of the present disclosure;

FIGS. 7 to 26 illustrate examples of one or more stages in a manufacturing method of a trench semiconductor structure according to embodiments of the present disclosure; and

FIGS. 27 to 30 illustrate examples of one or more stages in another manufacturing method of a trench semiconductor structure according to embodiments of the present disclosure.

The same or similar components are marked with the same reference numerals in the drawings and detailed description. Embodiments of the present disclosure will be readily understood from the following detailed description in conjunction with the accompanying drawings.

### DETAILED DESCRIPTION OF ILLUSTRATIVE EMBODIMENTS

The making and using of embodiments of this disclosure are discussed in detail below. It should be appreciated, however, that the concepts disclosed herein can be embodied in a wide variety of specific contexts, and that the specific embodiments discussed herein are merely illustrative and do not serve to limit the scope of the claims. Further, it should be understood that various changes, substitutions and alterations can be made herein without departing from the spirit and scope of this disclosure as defined by the appended claims.

Furthermore, one or more features from one or more of the following described embodiments may be combined to create alternative embodiments not explicitly described, and features suitable for such combinations are understood to be within the scope of this disclosure. It is therefore intended that the appended claims encompass any such modifications or embodiments.

The following disclosure provides various different embodiments or examples for implementing different features of the presented subject matter. Specific embodiments of components and configurations are described below. Certainly, these are examples only and are not intended to be limiting. In this disclosure, references to forming a first feature over or on a second feature may include embodiments where the first and second features are formed in direct contact, and may also include embodiments where an additional feature is formed between the first feature and the second feature such that the first feature and the second feature may not be in direct contact. In addition, the present disclosure may repeat reference signs and/or letters in various embodiments. Such repetition is for simplicity and clarity and does not in itself indicate relationships between the various embodiments and/or configurations discussed.

Embodiments of the present disclosure are discussed in detail below. It should be appreciated, however, that the present disclosure provides applicable concepts that can be embodied in a wide variety of specific contexts. The specific embodiments discussed herein are illustrative only, and do not limit the scope of the present disclosure.

Embodiments of the present disclosure provide a trench semiconductor structure and a manufacturing method thereof. In the trench semiconductor structure of embodiments of the present disclosure, a super-barrier-rectifier (SBR) and a shielded gate trench metal oxide semiconductor field effect transistor (SGT MOSFET) are integrated, and the channel lengths of the SBR and the SGT MOSFET may be adjusted independently, so that the performance of the trench semiconductor structure can be flexibly adjusted according to demand.

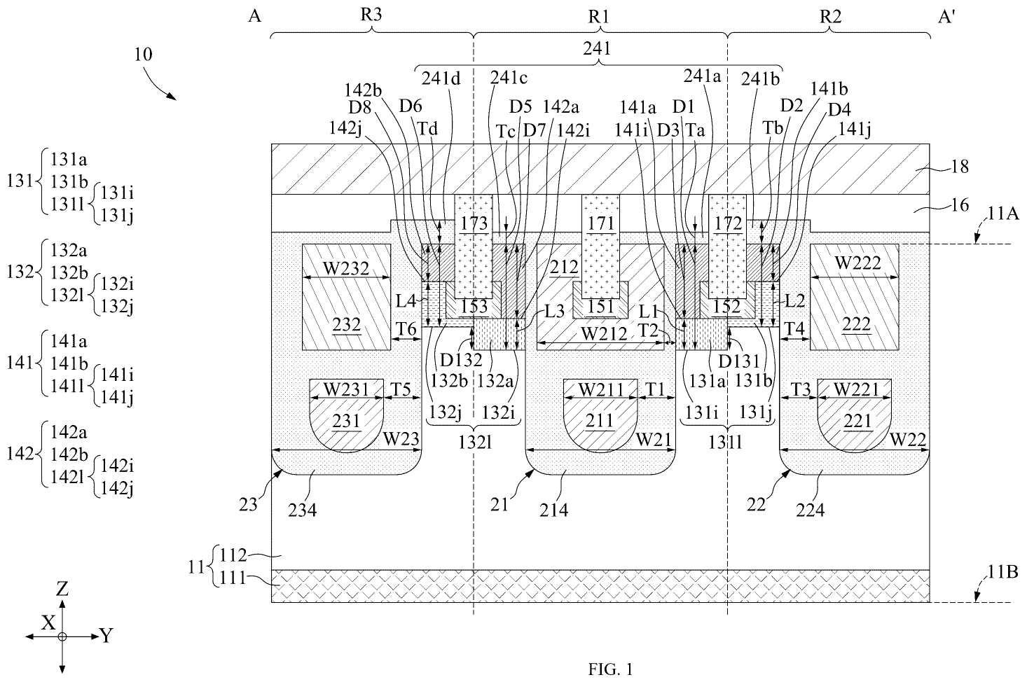

FIG. 1 is a cross-sectional view of an example trench semiconductor structure 10 according to embodiments of the present disclosure. Specifically, the trench semiconductor structure 10 is a trench MOS rectifier structure having a vertical current conduction path. For example, the current of the trench semiconductor structure 10 may be conducted vertically through the trench semiconductor structure 10.

In some embodiments, referring to FIG. 1, the trench semiconductor structure 10 includes a semiconductor material layer 11, a first trench structure 21, a second trench structure 22, a first doped block 131, and a second doped block 141. In some embodiments, the trench semiconductor structure 10 further may include a third trench structure 23, a third doped block 132, a fourth doped block 142, an interlayer dielectric layer 16, and a metal layer 18. The four doped blocks 131, 141, 132 and 142 may also be referred to as doped regions, and “block” is used herein for the convenience of description.

In some embodiments, the semiconductor material layer 11 includes a substrate 111 and an epitaxial layer 112 located on the substrate 111. In some embodiments, the substrate 111 includes, for example, silicon, silicon carbide (SiC), germanium (Ge), silicon germanium (SiGe), gallium nitride (GaN), gallium arsenide (GaAs), gallium arsenide phosphide (GaAsP), or other semiconductor materials. In some embodiments, the epitaxial layer 112 includes, for example, silicon, silicon carbide (SiC), germanium (Ge), silicon germanium (SiGe), gallium nitride (GaN), gallium arsenide (GaAs), gallium arsenide phosphide (GaAsP), or other semiconductor materials. The substrate 111 may be an N-type or P-type semiconductor material. The epitaxial layer 112 may be an N-type or P-type semiconductor material. In some embodiments, the substrate 111 and the epitaxial layer 112 have the same conductivity type, for example, the substrate 111 and the epitaxial layer 112 are both N-type.

The substrate 111 may have doping of the same conductivity type as the epitaxial layer 112. In some embodiments, the substrate 111 is a part of a silicon substrate or a silicon wafer. In some embodiments, the doping concentration of the substrate 111 is greater than the doping concentration of the epitaxial layer 112.

In some embodiments, the semiconductor material layer 11 is defined with a first region R1 and a second region R2 adjacent to the first region R1. The first region R1 includes an SBR, and the second region R2 includes an SGT MOSFET. In some embodiments, the semiconductor material layer 11 is further defined with a third region R3 adjacent to the first region R1. In some embodiments, the first region R1 is located between the second region R2 and the third region R3, or is surrounded by the second region R2 and the third region R3. The third region R3 may also include an SGT MOSFET.

The semiconductor material layer 11 may have a first surface 11A and a second surface 11B opposite to the first surface 11A. The second surface 11B and the first surface 11A may be located on opposite sides of the semiconductor material layer 11. The first surface 11A and the second surface 11B may be horizontal planes. For the convenience of description, the direction perpendicular to the first surface 11A and the second surface 11B is defined as a vertical direction Z, and a plane formed by a first direction X and a second direction Y is perpendicular to the vertical direction Z and parallel to the first surface 11A and the second surface 11B. In some embodiments, the first surface 11A may be the active surface of the epitaxial layer 112. The bottom surface of the substrate 111 is the second surface 11B, and the top surface of the epitaxial layer 112 is the first surface 11A.

The first trench structure 21 extends from the first surface 11A toward the second surface 11B. The first trench structure 21 includes a first electrode 211, a second electrode 212 located above the first electrode 211, and a first oxide layer 214 surrounding the first electrode 211 and the second electrode 212 and separating the first electrode 211 and the second electrode 212 from each other. In some embodiments, the first electrode 211 and the second electrode 212 are columnar structures. In some embodiments, the top surface of the first trench structure 21 is coplanar with the first surface 11A. In some embodiments, the top surface of the second electrode 212 is coplanar with the first surface 11A. In a top view of the trench semiconductor structure 10, the first trench structure 21 extends in the first direction X parallel to the first surface 11A, and the second electrode 212 overlaps with the first electrode 211 located below the second electrode 212.

The first oxide layer 214 is used to electrically isolate the epitaxial layer 112 from the first electrode 211 and the second electrode 212. In other words, the first electrode 211 and the second electrode 212 are separated from the epitaxial layer 112 by the first oxide layer 214 in the trench of the first trench structure 21. The first electrode 211 and the second electrode 212 are respectively surrounded by the first oxide layer 214. At least a portion of the first oxide layer 214 is located between the first electrode 211 and the second electrode 212. In some embodiments, the first oxide layer 214 located between the first electrode 211 and the semiconductor material layer 11 has a first thickness T1, the first oxide layer 214 located between the second electrode 212 and the semiconductor material layer 11 has a second thickness T2. In some embodiments, the second thickness T2 is less than the first thickness T1. In some embodiments, the first thickness T1 and the second thickness T2 are substantially the same. The first thickness T1 and the second thickness T2 may be adjusted according to the sizes or operating voltages of the first electrode 211 and the second electrode 212, respectively.

In some embodiments, the first electrode 211 has a first width W211 (in the second direction Y), the second electrode 212 has a second width W212 (in the second direction Y). In some embodiments, the second width W212 is greater than the first width W211. In some embodiments, the first width W211 and the second width W212 are substantially the same.

The second trench structure 22 is spaced apart from the first trench structure 21 in the semiconductor material layer 11. The first doped block 131 and the second doped block 141 are located between the first trench structure 21 and the second trench structure 22. The trench depth of the first trench structure 21 and the trench depth of the second trench structure 22 may be the same or different, and the trench width W21 of the first trench structure 21 and the trench width W22 of the second trench structure 22 may be the same or different. In some embodiments, the trench depth of the first trench structure 21 and the trench depth of the second trench structure 22 are the same. The trench width W21 of the first trench structure 21 and the trench width W22 of the second trench structure 22 may be the same.

The second trench structure 22 extends from the first surface 11A toward the second surface 11B. The second trench structure 22 includes a third electrode 221, a first gate 222 located above the third electrode 221, and a second oxide layer 224 separating the third electrode 221 and the first gate 222 from each other. The second oxide layer 224 surrounds the third electrode 221 and the first gate 222. The first doped block 131 is located between the second electrode 212 and the first gate 222. In some embodiments, the third electrode 221 and the first gate 222 are columnar structures. In some embodiments, the top surface of the second trench structure 22 is coplanar with the first surface 11A. In some embodiments, the top surface of the first gate 222 is coplanar with the first surface 11A. In the top view of the trench semiconductor structure 10, the second trench structure 22 extends in the first direction X parallel to the first surface 11A, and the first gate 222 overlaps with the third electrode 221 below.

The second oxide layer 224 is used to electrically isolate the third electrode 221 and the first gate 222 from the epitaxial layer 112. In other words, the third electrode 221 and the first gate 222 are separated from the epitaxial layer 112 by the second oxide layer 224 in the trench of the second trench structure 22. The third electrode 221 and the first gate 222 are respectively surrounded by the second oxide layer 224. At least a portion of the second oxide layer 224 is located between the third electrode 221 and the first gate 222. At least a portion of the second oxide layer 224 serves as a gate oxide layer of the SGT MOSFET located in the second region R2. In some embodiments, the second oxide layer 224 located between the third electrode 221 and the semiconductor material layer 11 has a third thickness T3, and the second oxide layer 224 located between the first gate 222 and the semiconductor material layer 11 has a fourth thickness T4. In some embodiments, the third thickness T3 is greater than the fourth thickness T4. In some embodiments, the third thickness T3 and the fourth thickness T4 are substantially the same. The third thickness T3 and the fourth thickness T4 may be adjusted according to the sizes or operating voltages of the third electrode 221 and the first gate 222, respectively.

In some embodiments, the third electrode 221 has a third width W221, and the first gate 222 has a fourth width W222. In some embodiments, the fourth width W222 is greater than the third width W221. In some embodiments, the third width W221 is substantially the same as the fourth width W222.

The semiconductor material layer 11 between the first trench structure 21 and the second trench structure 22 forms a mesa surface. In some embodiments, the mesa surface separates the first trench structure 21 from the second trench structure 22. The width of the mesa surface may be controlled based on the positions of the first trench structure 21 and the second trench structure 22.

The semiconductor material layer 11 includes the first doped block 131. The first doped block 131 is located in the semiconductor material layer 11 away from the first surface 11A and between the first trench structure 21 and the second trench structure 22, and serves as a doped body region of the trench semiconductor structure 10. The first doped block 131 is disposed between the first surface 11A and the second surface 11B, and at least a portion of the epitaxial layer 112 is disposed between the first doped block 131 and the substrate 111. In the top view of the trench semiconductor structure 10, the first doped block 131 extends in the first direction X. In some embodiments, the first doped block 131 is adjacent to the first oxide layer 214 and separated from the second electrode 212, and adjacent to the second oxide layer 224 and separated from the first gate 222. In some embodiments, the first doped block 131 is located in the epitaxial layer 112 and contacts the first oxide layer 214 and the second oxide layer 224. At least a portion of the first oxide layer 214 is located between the second electrode 212 and the first doped block 131. At least a portion of the second oxide layer 224 is located between the first gate 222 and the first doped region 131.

In some embodiments, the first doped block 131 has a conductivity type different from that of the epitaxial layer 112, for example, a conductivity type of a second type. In some embodiments, the first doped block 131 has a P-type, and the epitaxial layer 112 has an N-type. The first doped block 131 includes a P-type dopant, and the P-type dopant may be, for example, boron, aluminum, gallium, indium, etc. In some embodiments, the P-type dopant included in the first doped block 131 is boron. The doping concentration of the first doped block 131 is greater than the doping concentration of the epitaxial layer 112. The depth of the first doped block 131 is less than the depth of the first electrode 211. The depth of the first doped block 131 is less than or equal to the depth of the bottom surface of the second electrode 212. As used herein, the depth of an entity in the epitaxial layer 112 is a distance from the first surface 11A to a bottom of the entity, unless otherwise provided.

The first doped block 131 is defined with a first boundary 1311 in the semiconductor material layer 11. The first boundary 1311 separates the epitaxial layer 112 having a different conductivity type from the first doped block 131. The first boundary 1311 includes a first portion 131i and a second portion 131j, the first portion 131i is adjacent to the first trench structure 21, and the second portion 131j of the first boundary 1311 is adjacent to the second trench structure 22. The first portion 131i is located in the first region R1, and the second portion 131j is located in the second region R2. In some embodiments, a distance D1 between the first portion 131i and the first surface 11A is different from a distance D2 between the second portion 131j and the first surface 11A. In some embodiments, the distance D1 between the first portion 131i and the first surface 11A is greater than the distance D2 between the second portion 131j and the first surface 11A.

A difference between the distance D1 and the distance D2 is a distance D131. The distance D131 is the difference between the depth of the bottom of a first doped region 131a and the depth of the bottom of a second doped region 131b along the vertical direction Z. In some embodiments, the distance D131 is greater than zero.

The first doped block 131 includes the first doped region 131a and the second doped region 131b. The first doped region 131a and the second doped region 131b are adjacent to and in contact with each other. The first doped region 131a is located in the first region R1, and the second doped region 131b is located in the second region R2. In some embodiments, the first doped region 131a is in contact with the first oxide layer 214. The second doped region 131b is located between the first doped region 131a and the second trench structure 22, and in contact with the second oxide layer 224.

The first portion 131i of the first boundary 1311 is the bottom surface of the first doped region 131a, and the second portion 131j of the first boundary 1311 is the bottom surface of the second doped region 131b. In some embodiments, the bottom surface of the first doped region 131a or the bottom surface of the second doped region 131b is located at approximately the same level as the bottom surface of the second electrode 212. The first portion 131i of the first boundary 1311 or the second portion 131j of the first boundary 1311 may be located at approximately the same level as the bottom surface of the second electrode 212. In some embodiments, the bottom surface of the first doped region 131a or the bottom surface of the second doped region 131b is located at approximately the same level as the bottom surface of the first gate 222. The first portion 131i of the first boundary 1311 or the second portion 131j of the first boundary 1311 may be located at approximately the same level as the bottom surface of the first gate 222.

The semiconductor material layer 11 includes the second doped block 141. The second doped block 141 is located between the first surface 11A and the first doped block 131. In the top view of the trench semiconductor structure 10, the second doped block 141 extends in the first direction X. In some embodiments, the second doped block 141 is adjacent to the first oxide layer 214 and separated from the second electrode 212, and adjacent to the second oxide layer 224 and separated from the first gate 222. In some embodiments, the second doped block 141 is located in the epitaxial layer 112 and contacts the first oxide layer 214 and the second oxide layer 224. At least a portion of the first oxide layer 214 is located between the second electrode 212 and the second doped block 141. At least a portion of the second oxide layer 224 is located between the first gate 222 and the second doped block 141.

In some embodiments, the second doped block 141 has the same conductivity type as the epitaxial layer 112, for example, a first conductivity type. In some embodiments, the second doped block 141 and the epitaxial layer 112 are both N-type. The doping concentration of the second doped block 141 may be greater than the doping concentration of the epitaxial layer 112. The depth of the second doped block 141 may be less than the depth of the bottom surface of the second electrode 212. The depth of the second doped block 141 may be less than the depth of the bottom surface of the first gate 222.

The second doped block 141 is defined with a second boundary 1411 between the second doped block 141 and the first doped block 131. The second boundary 1411 separates the first doped block 131 and the second doped block 141 of different conductivity types. The second boundary 1411 includes a third portion 141i and a fourth portion 141j, the third portion 141i is adjacent to the first trench structure 21, and the fourth portion 141j of the second boundary 1411 is adjacent to the second trench structure 22. The third portion 141i is located in the first region R1, and the fourth portion 141j is located in the second region R2. In some embodiments, a distance D3 between the third portion 141i and the first surface 11A is different from a distance D4 between the fourth portion 141j and the first surface 11A. In some embodiments, the distance D3 between the third portion 141i and the first surface 11A is greater than the distance D4 between the fourth portion 141j and the first surface 11A.

The distance D1 between the first portion 131i of the first boundary 1311 and the first surface 11A is greater than the distance D3 between the third portion 141i of the second boundary 1411 and the first surface 11A. The first portion 131i and the third portion 141i overlap in the top view of the trench semiconductor structure 10. The distance D2 between the second portion 131j of the first boundary 1311 and the first surface 11A is greater than the distance D4 between the fourth portion 141j of the second boundary 1411 and the first surface 11A. The second portion 131j and the fourth portion 141j overlap in the top view of the trench semiconductor structure 10. The doping concentration of the first doped block 131 between the first portion 131i of the first boundary 1311 and the third portion 141i of the second boundary 1411 is different from the doping concentration of the first doped block 131 between the second portion 131j of the first boundary 1311 and the fourth portion 141j of the second boundary 1411. In other words, the doping concentration of the first doped region 131a is different from the doping concentration of the second doped region 131b.

The second doped block 141 includes a third doped region 141a and a fourth doped region 141b having the first conductivity type. The third doped region 141a and the fourth doped region 141b are adjacent to and in contact with each other. In some embodiments, the third doped region 141a is in contact with the first oxide layer 214, and the fourth doped region 141b is located between the third doped region 141a and the second trench structure 22 and in contact with the second oxide layer 224. The third doped region 141a is located in the semiconductor material layer 11 and between the first surface 11A and the first doped region 131a. The fourth doped region 141b is located in the semiconductor material layer 11 and between the first surface 11A and the second doped region 131b. The third doped region 141a is located in the first region R1, and the fourth doped region 141b is located in the second region R2. In some embodiments, when the distance D1 between the bottom surface of the first doped region 131a and the first surface 11A is greater than the distance D2 between the bottom surface of the second doped region 131b and the first surface 11A, the distance D3 between the third doped region 141a and the first surface 11A is greater than or equal to the distance D4 between the fourth doped region 141b and the first surface 11A. The third portion 141i of the second boundary 1411 is the bottom surface of the third doped region 141a, and the fourth portion 141j of the second boundary 1411 is the bottom surface of the fourth doped region 141b. In some embodiments, the distance D2 is greater than the distance D3.

The first doped region 131a is a SBR channel, and the second doped region 131b is a MOSFET channel. In some embodiments, the distance between the first portion 131i of the first boundary 1311 and the third portion 141i of the second boundary 1411 is the channel length L1 of the SBR. The distance between the second portion 131j of the first boundary 1311 and the fourth portion 141j of the second boundary 1411 is the channel length L2 of the SGT MOSFET. The channel length L1 of the SBR and the channel length L2 of the SGT MOSFET may be adjusted independently according to requirements. The sum of the channel length L1 of the SBR and the distance D3 is the distance D1, and the sum of the channel length L2 of the SGT MOSFET and the distance D4 is the distance D2. In some embodiments, the channel length L2 of the SGT MOSFET is greater than the channel length L1 of the SBR.

A fourth oxide layer 241 may be disposed on the first surface 11A of the semiconductor material layer 11 and between the interlayer dielectric layer 16 and the second doped block 141. The fourth oxide layer 241 may cover the first surface 11A, the first trench structure 21, the second trench structure 22, and the second doped block 141. The fourth oxide layer 241 includes a first region 241a and a second region 241b, the first region 241a is located above the first doped region 131a, and the second region 241b is located above the second doped region 131b. In other words, the first region 241a is located above the first portion 131i, and the second region 241b is located above the second portion 131j. In some embodiments, the first region 241a is located above the first doped region 131a and extends over the first trench structure 21. The second region 241b is located above the second doped region 131b and extends over the second oxide layer 224. In some embodiments, in the top view of the trench semiconductor structure, the first region 241a overlaps with the second electrode 212, and the second region 241b does not overlap with the first gate 222.

The thickness Ta of the first region 241a may be the same as or different from the thickness Tb of the second region 241b. In some embodiments, the thickness Ta of the first region 241a is less than the thickness Tb of the second region 241b. In some embodiments, when the distance D1 between the first doped region 131a and the first surface 11A is greater than the distance D2 between the second doped region 131b and the first surface 11A, the thickness Ta of the first region 241a is less than the thickness Tb of the second region 241b. The thickness Ta of the first region 241a and the thickness Tb of the second region 241b of the fourth oxide layer 241 may be respectively less than the first thickness T1 of the first oxide layer 214 located between the first electrode 211 and the semiconductor material layer 11.

The third trench structure 23 is spaced apart from the first trench structure 21. The third doped block 132 and the fourth doped block 142 are located between the first trench structure 21 and the third trench structure 23. The trench depth of the first trench structure 21 and the trench depth of the third trench structure 23 may be the same or different, and the trench width W21 of the first trench structure 21 and the trench width W23 of the third trench structure 23 may be the same or different. In some embodiments, the trench depth of the first trench structure 21 and the trench depth of the third trench structure 23 are the same, and the trench width W21 of the first trench structure 21 and the trench width W23 of the third trench structure 23 are the same.

The third trench structure 23 extends from the first surface 11A toward the second surface 11B. The third trench structure 23 includes a fourth electrode 231, a second gate 232 located above the fourth electrode 231, and a third oxide layer 234 surrounding the fourth electrode 231 and the second gate 232 and separating them from each other. The third doped block 132 is located between the second electrode 212 and the second gate 232. In some embodiments, the fourth electrode 231 and the second gate 232 are columnar structures. In some embodiments, the top surface of the third trench structure 23 is coplanar with the first surface 11A. In some embodiments, the top surface of the second gate 232 is coplanar with the first surface 11A. In the top view of the trench semiconductor structure 10, the third trench structure 23 extends in the first direction X parallel to the first surface 11A, and the second gate 232 overlaps with the fourth electrode 231 below.

The third oxide layer 234 is used to electrically isolate the fourth electrode 231 and the second gate 232 from the epitaxial layer 112. In other words, the fourth electrode 231 and the second gate 232 are separated from the epitaxial layer 112 by the third oxide layer 234 in the trench of the third trench structure 23. The fourth electrode 231 and the second gate 232 are respectively surrounded by the third oxide layer 234. At least a portion of the third oxide layer 234 is located between the fourth electrode 231 and the second gate 232. At least a portion of the third oxide layer 234 serves as a gate oxide layer of the SGT MOSFET located in the third region R3. In some embodiments, the fourth oxide layer 241, the first oxide layer 214, the second oxide layer 224, and the third oxide layer 234 include the same material or different materials.

In some embodiments, the third oxide layer 234 between the fourth electrode 231 and the semiconductor material layer 11 has a fifth thickness T5, the third oxide layer 234 between the second gate 232 and the semiconductor material layer 11 has a sixth thickness T6. In some embodiments, the fifth thickness T5 is greater than the sixth thickness T6. In some embodiments, the fifth thickness T5 is substantially the same as the sixth thickness T6. The fifth thickness T5 and the sixth thickness T6 may be adjusted according to the sizes or operating voltages of the fourth electrode 231 and the second gate 232, respectively.

In some embodiments, the fourth electrode 231 has a fifth width W231, the second gate 232 has a sixth width W232. In some embodiments, the sixth width W232 is greater than the fifth width W231. In some embodiments, the fifth width W231 is substantially the same as the sixth width W232.

The semiconductor material layer 11 between the first trench structure 21 and the third trench structure 23 may form a mesa surface. In some embodiments, the mesa surface separates the first trench structure 21 from the third trench structure 23. The width of the mesa surface may be controlled by the positions of the first trench structure 21 and the third trench structure 23.

The semiconductor material layer 11 includes the third doped block 132. The third doped block 132 is located in the semiconductor material layer 11, away from the first surface 11A and between the first trench structure 21 and the third trench structure 23, and serves as a doped body region of the trench semiconductor structure 10. The third doped block 132 is disposed between the first surface 11A and the second surface 11B, and at least a portion of the epitaxial layer 112 is disposed between the third doped block 132 and the substrate 111. In the top view, the third doped block 132 extends in the first direction X. In some embodiments, the third doped block 132 is adjacent to the first oxide layer 214 and separated from the second electrode 212, and adjacent to the third oxide layer 234 and separated from the second gate 232. In some embodiments, the third doped block 132 is located in the epitaxial layer 112 and contacts the first oxide layer 214 and the third oxide layer 234. At least a portion of the first oxide layer 214 is located between the second electrode 212 and the third doped block 132. At least a portion of the third oxide layer 234 is located between the second gate 232 and the third doped block 132.

In some embodiments, the third doped block 132 has a conductivity type different from that of the epitaxial layer 112, for example, a conductivity type of the second type. In some embodiments, the third doped block 132 has the P-type, and the epitaxial layer 112 has the N-type. The third doped block 132 includes a P-type dopant, and the P-type dopant may be, for example, boron, aluminum, gallium, indium, etc. In some embodiments, the P-type dopant included in the third doped block 132 is boron. The doping concentration of the third doped block 132 is greater than the doping concentration of the epitaxial layer 112. The depth of the third doped block 132 is less than the depth of the first electrode 211. The depth of the third doped block 132 is less than or equal to the depth of the bottom surface of the second electrode 212. The depth of the third doped block 132 may be substantially the same as the depth of the first doped block 131.

The third doped block 132 is defined with a third boundary 1321 of the third doped block 132 in the semiconductor material layer 11. The third boundary 1321 separates the epitaxial layer 112 having a different conductivity type from the third doped block 132. The third boundary 1321 includes a fifth portion 132i and a sixth portion 132j, the fifth portion 132i is adjacent to the first trench structure 21, and the sixth portion 132j of the third boundary 1321 is adjacent to the third trench structure 23. The fifth portion 132i is located in the first region R1, and the sixth portion 132j is located in the third region R3. In some embodiments, a distance D5 between the fifth portion 132i and the first surface 11A is different from a distance D6 between the sixth portion 132j and the first surface 11A. In some embodiments, the distance D5 between the fifth portion 132i and the first surface 11A is greater than the distance D6 between the sixth portion 132j and the first surface 11A.

A difference between the distance D5 and the distance D6 is a distance D132. The distance D132 is the difference between the depth of the bottom of a fifth doped region 132a and the depth of the bottom of a sixth doped region 132b along the vertical direction Z. In some embodiments, the distance D132 is greater than zero.

The distance D1 between the first portion 131i and the first surface 11A and the distance D5 between the fifth portion 132i and the first surface 11A may be the same or different. The distance D2 between the second portion 131j and the first surface 11A and the distance D6 between the sixth portion 132j and the first surface 11A may be the same or different. In some embodiments, the first portion 131i and the fifth portion 132i are coplanar, and the distance D1 and the distance D5 are substantially the same. In some embodiments, the second portion 131j and the sixth portion 132j are coplanar, and the distance D2 and the distance D6 are substantially the same.

The third doped block 132 includes the fifth doped region 132a and the sixth doped region 132b. The fifth doped region 132a and the sixth doped region 132b are adjacent to and in contact with each other. The fifth doped region 132a is located in the first region R1, and the sixth doped region 132b is located in the third region R3. In some embodiments, the fifth doped region 132a is in contact with the first oxide layer 214, and the sixth doped region 132b is located between the fifth doped region 132a and the third trench structure 23 and in contact with the third oxide layer 234.

The first doped block 131 and the third doped block 132 are respectively located on two sides of the first trench structure 21 and are arranged opposite to each other. In some embodiments, the doping concentration of the first doped region 131a is substantially the same as the doping concentration of the fifth doped region 132a. In some embodiments, the doping concentration of the second doped region 131b is substantially the same as the doping concentration of the sixth doped region 132b.

The fifth portion 132i of the third boundary 1321 is the bottom surface of the fifth doped region 132a, and the sixth portion 132j of the third boundary 1321 is the bottom surface of the sixth doped region 132b. The bottom surface of the fifth doped region 132a or the bottom surface of the sixth doped region 132b is located at approximately the same level as the bottom surface of the second electrode 212. The fifth portion 132i of the third boundary 1321 or the sixth portion 132j of the third boundary 1321 is located at approximately the same level as the bottom surface of the second electrode 212. The bottom surface of the fifth doped region 132a or the bottom surface of the sixth doped region 132b is located at approximately the same level as the bottom surface of the second gate 232. The fifth portion 132i of the third boundary 1321 or the sixth portion 132j of the third boundary 1321 is located at approximately the same level as the bottom surface of the second gate 232.

The semiconductor material layer 11 includes the fourth doped block 142. The fourth doped block 142 is located between the first surface 11A and the third doped block 132. In the top view of the trench semiconductor structure 10, the fourth doped block 142 extends in the first direction X. In some embodiments, the fourth doped block 142 is adjacent to the first oxide layer 214 and separated from the second electrode 212, and adjacent to the third oxide layer 234 and separated from the second gate 232. In some embodiments, the fourth doped block 142 is located in the epitaxial layer 112 and contacts the first oxide layer 214 and the third oxide layer 234. At least a portion of the first oxide layer 214 is located between the second electrode 212 and the fourth doped block 142. At least a portion of the third oxide layer 234 is located between the second gate 232 and the fourth doped block 142.

In some embodiments, the fourth doped block 142 has the same conductivity type as the epitaxial layer 112, for example, the first conductivity type. In some embodiments, both the fourth doped block 142 and the epitaxial layer 112 have the N-type. The doping concentration of the fourth doped block 142 is greater than the doping concentration of the epitaxial layer 112. The depth of the fourth doped block 142 is less than the depth of the bottom surface of the second electrode 212. The depth of the fourth doped block 142 is less than the depth of the bottom surface of the second gate 232.

The fourth doped block 142 is defined with a fourth boundary 1421 between the fourth doped block 142 and the third doped block 132. The fourth boundary 1421 separates the third doped block 132 and the fourth doped block 142 having different conductivity types. The fourth boundary 1421 includes a seventh portion 142i and an eighth portion 142j, the seventh portion 142i is adjacent to the first trench structure 21, and the eighth portion 142j of the fourth boundary 1421 is adjacent to the third trench structure 23. The seventh portion 142i is located in the first region R1, and the eighth portion 142j is located in the third region R3. In some embodiments, a distance D7 between the seventh portion 142i and the first surface 11A is different from a distance D8 between the eighth portion 142j and the first surface 11A. In some embodiments, the distance D7 between the seventh portion 142i and the first surface 11A is greater than the distance D8 between the eighth portion 142j and the first surface 11A.

The distance D5 between the fifth portion 132i of the third boundary 1321 and the first surface 11A is greater than the distance D7 between the seventh portion 142i of the fourth boundary 1421 and the first surface 11A. the fifth portion 132i and the seventh portion 142i overlap in the top view. The distance D6 between the sixth portion 132j of the third boundary 1321 and the first surface 11A is greater than the distance D8 between the eighth portion 142j of the fourth boundary 1421 and the first surface 11A. The sixth portion 132j and the eighth portion 142j overlap in the top view. The doping concentration of the third doped block 132 between the fifth portion 132i of the third boundary 1321 and the seventh portion 142i of the fourth boundary 1421 is different from the doping concentration of the third doped block 132 between the sixth portion 132j of the third boundary 1321 and the eighth portion 142j of the fourth boundary 1421. In other words, the doping concentration of the fifth doped region 132a is different from the doping concentration of the sixth doped region 132b.

The distance D3 between the third portion 141i and the first surface 11A and the distance D7 between the seventh portion 142i and the first surface 11A may be the same or different. The distance D4 between the fourth portion 141j and the first surface 11A and the distance D8 between the eighth portion 142j and the first surface 11A may be the same or different. In some embodiments, the third portion 141i and the seventh portion 142i are coplanar, and the distance D3 and the distance D7 are substantially the same. In some embodiments, the fourth portion 141j and the eighth portion 142j are coplanar, and the distance D4 and the distance D8 are substantially the same.

The fourth doped block 142 includes a seventh doped region 142a and an eighth doped region 142b having the first conductivity type. The seventh doped region 142a and the eighth doped region 142b are adjacent to and in contact with each other. In some embodiments, the seventh doped region 142a is in contact with the first oxide layer 214, and the eighth doped region 142b is located between the seventh doped region 142a and the third trench structure 23 and in contact with the third oxide layer 234. The seventh doped region 142a is located in the semiconductor material layer 11 and between the first surface 11A and the fifth doped region 132a. The eighth doped region 142b is located in the semiconductor material layer 11 and between the first surface 11A and the sixth doped region 132b. The seventh doped region 142a is located in the first region R1, and the eighth doped region 142b is located in the third region R3. In some embodiments, when the distance D5 between the fifth doped region 132a and the first surface 11A is greater than the distance D6 between the sixth doped region 132b and the first surface 11A, the distance D7 between the seventh doped region 142a and the first surface 11A is greater than or equal to the distance D8 between the eighth doped region 142b and the first surface 11A. The seventh portion 142i of the fourth boundary 1421 is the bottom surface of the seventh doped region 142a, and the eighth portion 142j of the fourth boundary 1421 is the bottom surface of the eighth doped region 142b. In some embodiments, the distance D6 is greater than the distance D7.

The second doped block 141 and the fourth doped block 142 are respectively located on two sides of the first trench structure 21 and are arranged opposite to each other. In some embodiments, the doping concentration of the third doped region 141a is substantially the same as the doping concentration of the seventh doped region 142a. In some embodiments, the doping concentration of the fourth doped region 141b is substantially the same as the doping concentration of the eighth doped region 142b. In some embodiments, the doping concentration of the third doped region 141a, the doping concentration of the fourth doped region 141b, the doping concentration of the seventh doped region 142a, and the doping concentration of the eighth doped region 142b are substantially the same.

In some embodiments, the distance between the fifth portion 132i of the third boundary 1321 and the seventh portion 142i of the fourth boundary 1421 is the channel length L3 of the SBR of the trench semiconductor structure 10. The distance between the sixth portion 132j of the third boundary 1321 and the eighth portion 142j of the fourth boundary 1421 is the channel length L4 of the SGT MOSFET in the third region R3. The channel length L3 of the SBR and the channel length L4 of the SGT MOSFET may be adjusted independently according to requirements. The sum of the channel length L3 of the SBR and the distance D7 is the distance D5, and the sum of the channel length L4 of the SGT MOSFET and the distance D8 is the distance D6. In some embodiments, the channel length L4 of the SGT MOSFET is greater than the channel length L3 of the SBR.

The trench semiconductor structure 10 includes an SBR. In some embodiments, the SBR is located in the first region R1, including the first electrode 211, the second electrode 212, the first doped region 131a, the third doped region 141a, the fifth doped region 132a and the seventh doped region 142a. The first trench structure 21, the first doped region 131a, the third doped region 141a, the fifth doped region 132a and the seventh doped region 142a are located in the first region R1. In some embodiments, the first region R1 including the SBR is surrounded by the second region R2 and the third region R3, each of the second region R2 and the third region R includes the SGT MOSFET. The second trench structure 22, the second doped region 131b and the fourth doped region 141b are located in the second region R2. The third trench structure 23, the sixth doped region 132b and the eighth doped region 142b are located in the third region R3.

The fourth oxide layer 241 may also cover the third trench structure 23 and the fourth doped block 142. The fourth oxide layer 241 includes a third region 241c and a fourth region 241d, the third region 241c is located above the fifth doped region 132a, and the fourth region 241d is located above the sixth doped region 132b. In other words, the third region 241c is located above the fifth portion 132i, and the fourth region 241d is located above the sixth portion 132j. In some embodiments, the third region 241c is located above the fifth doped region 132a and extends over the first trench structure 21. The fourth region 241d is located above the sixth doped region 132b and extends over the third oxide layer 234. In some embodiments, in the top view, the third region 241c overlaps with the first electrode 212, and the fourth region 241d does not overlap with the second gate 232.

The thickness Tc of the third region 241c may be the same as or different from the thickness Td of the fourth region 241d. In some embodiments, the thickness Tc of the third region 241c is less than the thickness Td of the fourth region 241d. In some embodiments, when the distance D5 between the fifth doped region 132a and the first surface 11A is greater than the distance D6 between the sixth doped region 132b and the first surface 11A, the thickness Tc of the third region 241c is less than the thickness Td of the fourth region 241d. In some embodiments, the thickness Ta of the first region 241a is substantially the same as the thickness Tc of the third region 241c, and the thickness Tb of the second region 241b is substantially the same as the thickness Td of the fourth region 241d. In some embodiments, the thickness Tc of the third region 241c and the thickness Td of the fourth region 241d of the fourth oxide layer 241 are respectively less than the first thickness T1 of the first oxide layer 214 located between the first electrode 211 and the semiconductor material layer 11.

The interlayer dielectric layer 16 is located over the first surface 11A of the semiconductor material layer 11, and the metal layer 18 is located on the interlayer dielectric layer 16. The interlayer dielectric layer 16 is used to separate the metal layer 18 from the semiconductor material layer 11, the first trench structure 21, the second trench structure 22, and the third trench structure 23. The interlayer dielectric layer 16 covers the first trench structure 21, the second trench structure 22, the third trench structure 23, the second doped block 141, and the fourth doped block 142.

In some embodiments, the interlayer dielectric layer 16 covers the fourth oxide layer 241. The fourth oxide layer 241 is located between the first surface 11A of the semiconductor material layer 11 and the interlayer dielectric layer 16. The fourth oxide layer 241 is located between the interlayer dielectric layer 16 and the first trench structure 21, the second trench structure 22, the third trench structure 23, the second doped block 141, and the fourth doped block 142.

In some embodiments, the metal layer 18 is the source of the trench semiconductor structure 10. In some embodiments, the metal layer 18 may be a patterned metal wire layer used for adjusting electrical paths according to actual operation requirements, and include multiple metal wires to electrically connect to different electrodes or doped regions. In some embodiments, the metal layer 18 may be the first metal layer (M1) in the interconnect structure. The metal layer 18 includes a conductive material, such as a metal, such as but not limited to, copper (Cu), gold (Au), silver (Ag), aluminum (Al), nickel (Ni), titanium (Ti), tungsten (W), tin (Sn), titanium nitride (TiN), aluminum silicon (AlSi) alloy, aluminum silicon copper (AlSiCu) alloy or other metals or alloys.

The second electrode 212, the first doped block 131, and the third doped block 132 are electrically connected to the metal layer 18, respectively. In some embodiments, a first conductive plug 171 may be provided extending through the interlayer dielectric layer 16, and the first conductive plug 171 may be at least partially surrounded by the second electrode 212, and electrically connected to the second electrode 212 and the metal layer 18. That is, the first conductive plug 171 extends through the interlayer dielectric layer 16 and into the second electrode 212. A second conductive plug 172 may be provided extending through the interlayer dielectric layer 16 and the second doped block 141, and the second conductive plug 172 may be at least partially surrounded by the first doped block 131, and electrically connected to the first doped block 131 and the metal layer 18. A third conductive plug 173 may be provided extending through the interlayer dielectric layer 16 and the fourth doped block 142, and the third conductive plug 173 may be at least partially surrounded by the third doped block 132, and electrically connected to the third doped block 132 and the metal layer 18. The first conductive plug 171, the second conductive plug 172, and the third conductive plug 173 extend from above the first surface 11A of the semiconductor material layer 11 along the vertical direction Z toward the second surface 11B. In some embodiments, the first conductive plug 171 is located in the first region R1, the second conductive plug 172 is located at the junction of the first region R1 and the second region R2, and the third conductive plug 173 is located at the junction of the second region R2 and the third region R3. In some embodiments, in the top view of the trench semiconductor structure 10, the first conductive plug 171, the second conductive plug 172, and the third conductive plug 173 extend in the first direction X. In some embodiments, the second electrode 212, the first doped block 131, the third doped block 132, the first conductive plug 171, the second conductive plug 172, the third conductive plug 173, and the metal layer 18 are all electrically connected to the source.

A first heavily doped region 151 may be provided in the second electrode 212 as a heavily doped region in the second electrode 212. The first heavily doped region 151 has the same conductivity type as the first doped block 131, for example, the P-type. In some embodiments, the doping concentration of the first heavily doped region 151 is greater than the doping concentration of the first doped block 131 or the second doped block 132. In some embodiments, the first heavily doped region 151 is located in the second electrode 212 and is separated from the first oxide layer 214. The first heavily doped region 151 is located below the first conductive plug 171, and a portion of the first heavily doped region 151 is located between the first conductive plug 171 and the second electrode 212. The first heavily doped region 151 surrounds the bottom of the first conductive plug 171 disposed in the second electrode 212, which reduces the ohmic contact resistance.

A second heavily doped region 152 may be provided in the first doped block 131 and serves as a heavily doped region in the first doped block 131. The second heavily doped region 152 has the same conductivity type as the first doped block 131, for example, the P-type. In some embodiments, the doping concentration of the second heavily doped region 152 is greater than the doping concentration of the first doped region 131a or the second doped region 131b. The second heavily doped region 152 is adjacent to the first doped region 131a, the second doped region 131b, the third doped region 141a, and the fourth doped region 141b. In some embodiments, the second heavily doped region 152 is located in the first doped block 131 and is separated from the first oxide layer 214 and the second oxide layer 224. In some embodiments, the second heavily doped region 152 is disposed between the adjacent first doped region 131a and the second doped region 131b. The second heavily doped region 152 is located below the second conductive plug 172, a portion of the second heavily doped region 152 is located between the second conductive plug 172 and the first trench structure 21, and another portion of the second heavily doped region 152 is located between the second conductive plug 172 and the second trench structure 22. The second heavily doped region 152 surrounds the bottom of the second conductive plug 172 disposed in the first doped block 131, which reduces the ohmic contact resistance. In some embodiments, the bottom of the second heavily doped region 152 may be at the same depth as the third portion 141i.

A third heavily doped region 153 may be provided in the third doped block 132, and serves as a heavily doped region in the third doped block 132. The third heavily doped region 153 has the same conductivity type as the third doped block 132, for example, the P-type. In some embodiments, the doping concentration of the third heavily doped region 153 is greater than the doping concentration of the fifth doped region 132a or the sixth doped region 132b. The third heavily doped region 153 is adjacent to the fifth doped region 132a, the sixth doped region 132b, the seventh doped region 142a, and the eighth doped region 142b. In some embodiments, the third heavily doped region 153 is located in the third doped block 132 and is separated from the first oxide layer 214 and the third oxide layer 234. In some embodiments, the third heavily doped region 153 is disposed between the adjacent fifth doped region 132a and the sixth doped region 132b. The third heavily doped region 153 is located below the third conductive plug 173, and a portion of the third heavily doped region 153 is located between the third conductive plug 173 and the first trench structure 21, and another portion of the third heavily doped region 153 is located between the third conductive plug 173 and the third trench structure 23. The third heavily doped region 153 surrounds the bottom of the third conductive plug 173 disposed in the third doped block 132, which reduces the ohmic contact resistance. In some embodiments, the bottom of the third heavily doped region 153 may be at the same depth as the seventh portion 142i. The bottoms of the first heavily doped region 151, the second heavily doped region 152 and the third heavily doped region 153 may be coplanar, i.e., have the same depth.

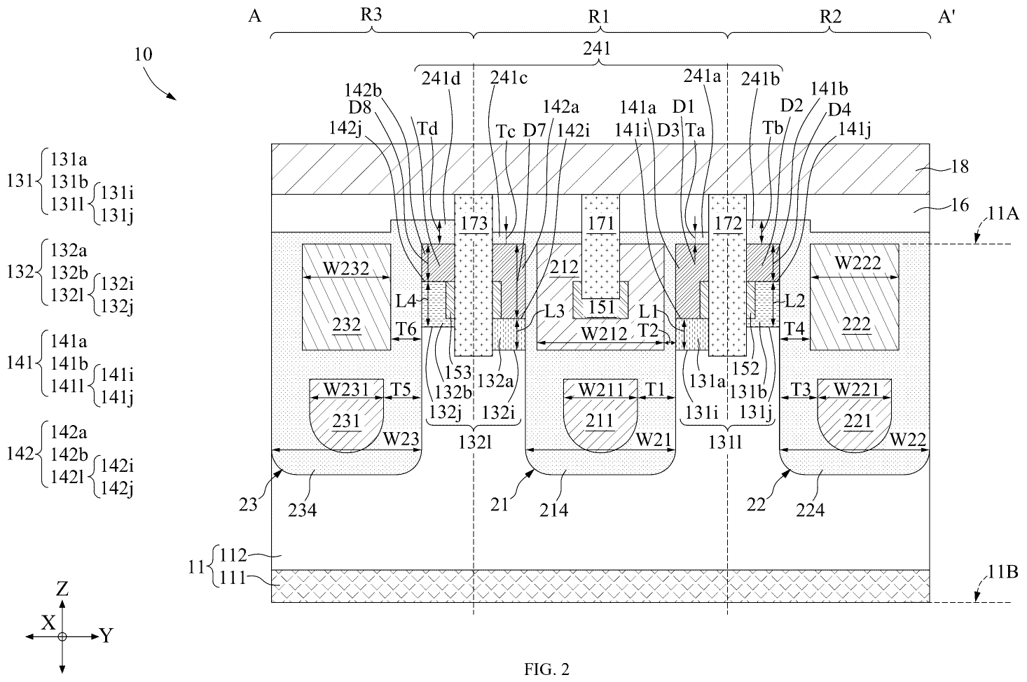

FIG. 2 is a cross-sectional view of another example trench semiconductor structure 10 according to embodiments of the present disclosure. The trench semiconductor structure 10 in FIG. 2 is similar to that described with respect to FIG. 1, however, with a different structure of the second conductive plug 172 and the third conductive plug 173. As shown in FIG. 2, in some embodiments, the second conductive plug 172 may extend through the first doped block 131 and the second heavily doped region 152, and the second heavily doped region 152 surrounds at least a portion of the second conductive plug 172. The first doped block 131 and the second heavily doped region 152 surround the second conductive plug 172 and are in contact with the second conductive plug 172, respectively, which reduces the starting voltage. The bottom of the second conductive plug 172 is located in the epitaxial layer 112. That is, the second conductive plug 172 extends through the interlayer dielectric layer 16, the second doped block 141, the second heavily doped region 152 and the first doped block 131, and extends into the epitaxial layer 112. In some embodiments, the third conductive plug 173 may extend through the third doped block 132 and the third heavily doped region 153, and the third heavily doped region 153 surrounds at least a portion of the third conductive plug 173. The third doped block 132 and the third heavily doped region 153 surround the third conductive plug 173 and are in contact with the third conductive plug 173, respectively, which reduces the starting voltage. The bottom of the third conductive plug 173 is located in the epitaxial layer 112. That is, the third conductive plug 173 extends through the interlayer dielectric layer 16, the fourth doped block 142, the third heavily doped region 153 and the third doped block 132, and extends into the epitaxial layer 112.

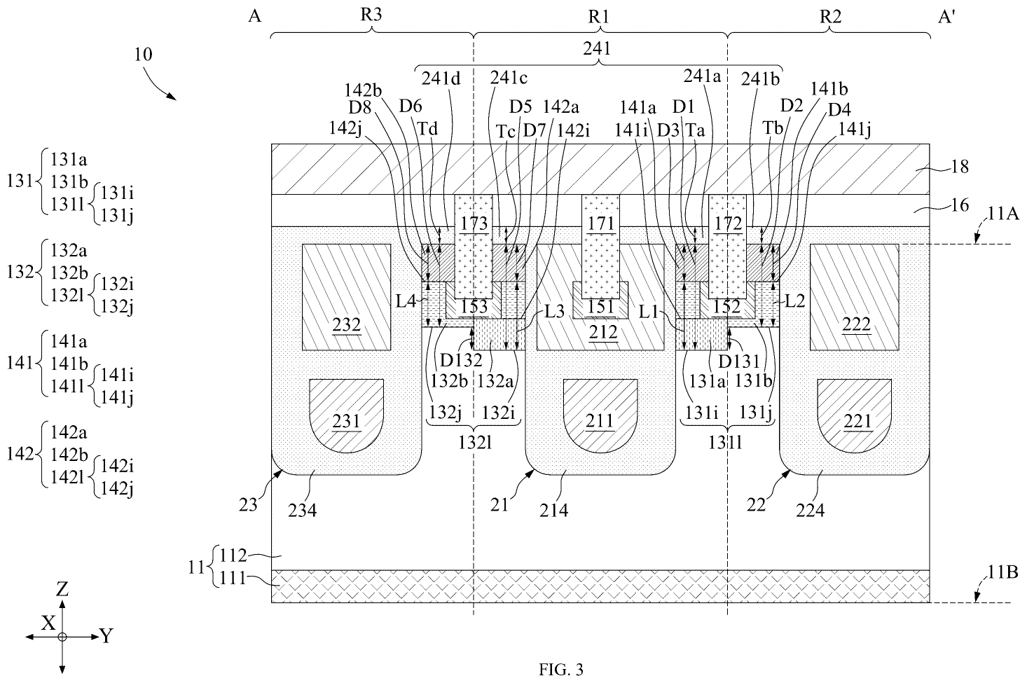

FIG. 3 is a cross-sectional view of another example trench semiconductor structure 10 according to embodiments of the present disclosure. The trench semiconductor structure 10 in FIG. 3 is similar to that described with respect to FIG. 1, however, with a different structure of the fourth oxide layer 241, the second doped block 141 and the fourth doped block 142. As shown, in some embodiments, the top surface of the first region 241a of the fourth oxide layer 241 is coplanar with the top surface of the second region 241b of the fourth oxide layer 241. The thickness Ta of the first region 241a is the same as the thickness Tb of the second region 241b. In some embodiments, when the top surface of the first region 241a is coplanar with the top surface of the second region 241b, the bottom surface of the third doped region 141a is coplanar with the bottom surface of the fourth doped region 141b. In other words, the third portion 141i of the second boundary 1411 is coplanar with the fourth portion 141j of the second boundary 1411. In some embodiments, the distance D3 between the third portion 141i and the first surface 11A is the same as the distance D4 between the fourth portion 141j and the first surface 11A.

In some embodiments, as shown, the top surface of the third region 241c of the fourth oxide layer 241 is coplanar with the top surface of the fourth region 241d of the fourth oxide layer 241. The thickness Tc of the third region 241c is the same as the thickness Td of the fourth region 241d. In some embodiments, when the top surface of the third region 241c is coplanar with the top surface of the fourth region 241d, the bottom surface of the seventh doped region 142a is coplanar with the bottom surface of the eighth doped region 142b. In other words, the seventh portion 142i and the eighth portion 142j of the fourth boundary 1421 are coplanar. In some embodiments, the distance D7 between the seventh portion 142i and the first surface 11A is the same as the distance D8 between the eighth portion 142j and the first surface 11A.

In some embodiments, the top surface of the first region 241a, the top surface of the second region 241b, the top surface of the third region 241c and the top surface of the fourth region 241d of the fourth oxide layer 241 are coplanar. The thickness Ta of the first region 241a, the thickness Tb of the second region 241b, the thickness Tc of the third region 241c and the thickness Td of the fourth region 241d are the same. In some embodiments, the second boundary 1411 and the fourth boundary 1421 are coplanar. The distance D3, the distance D4, the distance D7 and the distance D8 may be the same.

In some embodiments, the channel length L1 of the SBR is greater than the channel length L2 of the SGT MOSFET in the second region R2. In some embodiments, the channel length L3 of the SBR is greater than the channel length L4 of the SGT MOSFET in the third region R3.

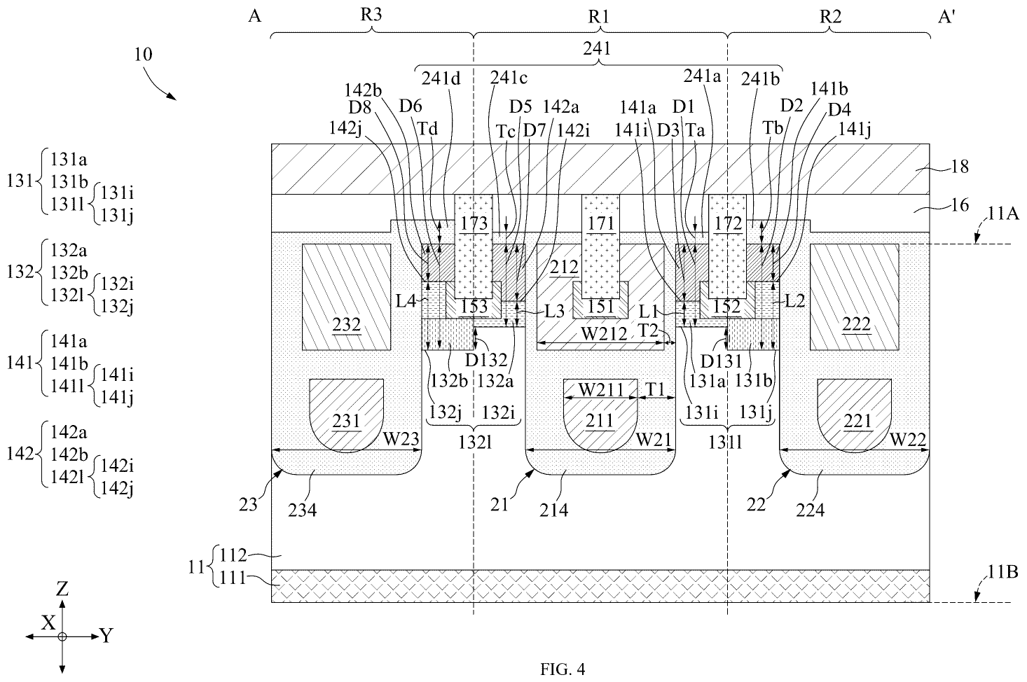

FIG. 4 is a cross-sectional view of another example trench semiconductor structure 10 according to embodiments of the present disclosure. The trench semiconductor structure 10 in FIG. 4 is similar to that described with respect to FIG. 1, however, with a different structure of the first doped block 131, the second doped block 141, the third doped block 132 and the fourth doped block 142. In some embodiments, when the thickness Ta of the first region 241a of the fourth oxide layer 241 is less than the thickness Tb of the second region 241b of the fourth oxide layer 241, the distance D1 between the first portion 131i of the first boundary 1311 and the first surface 11A may be less than the distance D2 between the second portion 131j and the first surface 11A, and the distance D3 between the third portion 141i of the second boundary 1411 and the first surface 11A may be greater than the distance D4 between the fourth portion 141j and the first surface 11A. In this example, the bottom depth of the second doped region 131b is greater than the bottom depth of the first doped region 131a.

In some embodiments, when the thickness Tc of the third region 241c of the fourth oxide layer 241 is less than the thickness Td of the fourth region 241d of the fourth oxide layer 241, the distance D5 between the fifth portion 132i of the third boundary 1321 and the first surface 11A may be less than the distance D6 between the sixth portion 132j and the first surface 11A, and the distance D7 between the seventh portion 142i of the fourth boundary 1421 and the first surface 11A may be greater than the distance D8 between the eighth portion 142j and the first surface 11A. In this example, the bottom depth of the sixth doped region 132b is greater than the bottom depth of the fifth doped region 132a.

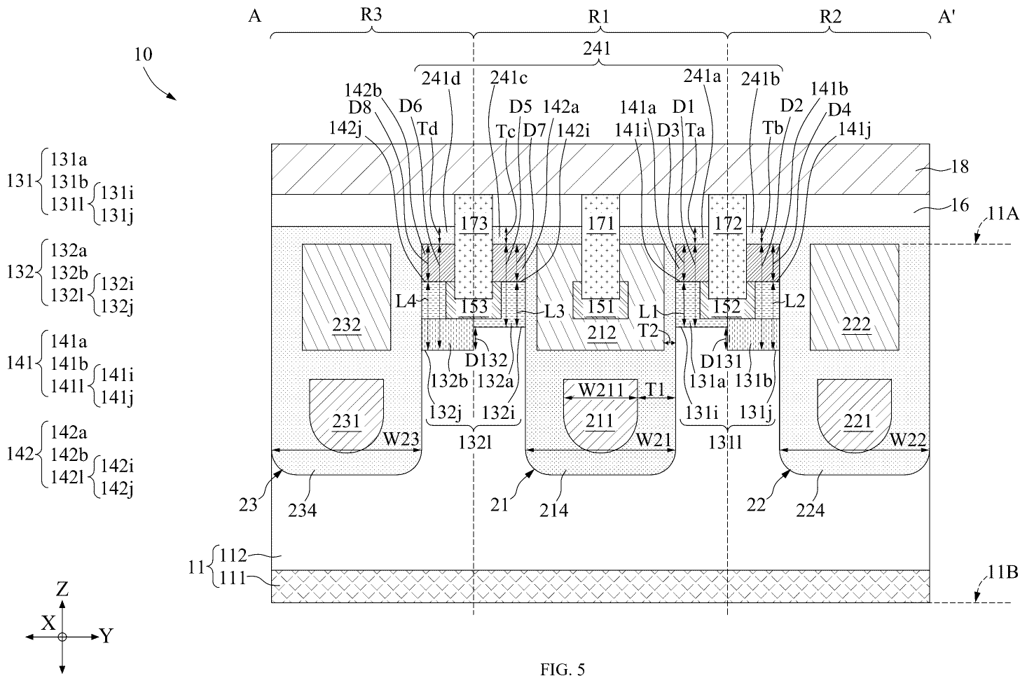

FIG. 5 is a cross-sectional view of another trench semiconductor structure 10 according to embodiments of the present disclosure. The trench semiconductor structure 10 in FIG. 5 is similar to that described with respect to FIG. 4, however, with a different structure of the fourth oxide layer 241, the second doped block 141, and the fourth doped block 142. In some embodiments, as shown, the top surface of the first region 241a of the fourth oxide layer 241 may be coplanar with the top surface of the second region 241b of the fourth oxide layer 241, the distance DI between the first portion 131i of the first boundary 1311 and the first surface 11A may be less than the distance D2 between the second portion 131j and the first surface 11A, and the distance D3 between the third portion 141i of the second boundary 1411 and the first surface 11A may be the same as the distance D4 between the fourth portion 141j and the first surface 11A. In this example, the bottom depth of the third doped region 141a is at approximately the same level as the bottom surface of the fourth doped region 141b.

In some embodiments, the top surface of the third region 241c of the fourth oxide layer 241 may be coplanar with the top surface of the fourth region 241d of the fourth oxide layer 241, the distance D5 between the fifth portion 132i of the third boundary 1321 and the first surface 11A may be less than the distance D6 between the sixth portion 132j and the first surface 11A, and the distance D7 between the seventh portion 142i of the fourth boundary 1421 and the first surface 11A may be the same as the distance D8 between the eighth portion 142j and the first surface 11A. In this example, the bottom depth of the seventh doped region 142a is located at approximately the same level as the bottom surface of the eighth doped region 142b.

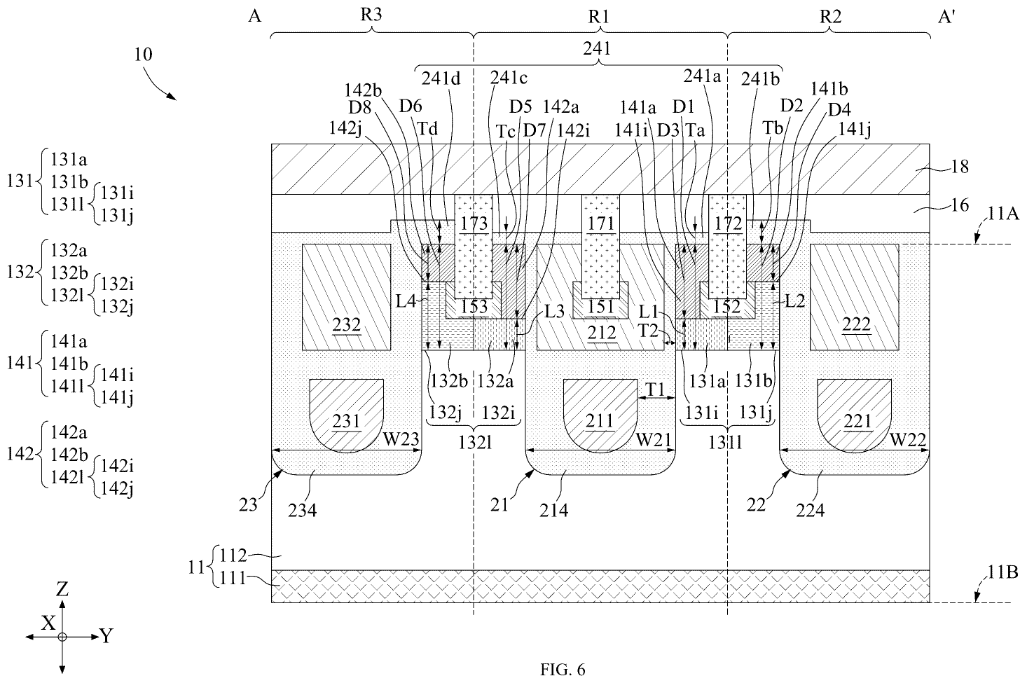

FIG. 6 is a cross-sectional view of another trench semiconductor structure 10 according to embodiments of the present disclosure. The trench semiconductor structure 10 in FIG. 6 is similar to that described with respect to FIG. 1, however, with a different structure of the first doped block 131 and the third doped block 132. In some embodiments, as shown, the thickness Ta of the first region 241a is less than the thickness Tb of the second region 241b, the distance D1 between the first portion 131i of the first boundary 1311 and the first surface 11A may be the same as the distance D2 between the second portion 131j and the first surface 11A, and the distance D3 between the third portion 141i of the second boundary 1411 and the first surface 11A may be greater than the distance D4 between the fourth portion 141j and the first surface 11A. In this example, the bottom surface of the first doped region 131a is coplanar with the bottom surface of the second doped region 131b. The difference D131 between the distance D1 and the distance D2 is zero.

In some embodiments, the thickness Tc of the third region 241c is less than the thickness Td of the fourth region 241d, the distance D5 between the fifth portion 132i of the third boundary 1321 and the first surface 11A may be the same as the distance D6 between the sixth portion 132j and the first surface 11A, and the distance D7 between the seventh portion 142i of the fourth boundary 1421 and the first surface 11A may be greater than the distance D8 between the eighth portion 142j and the first surface 11A. In this example, the bottom surface of the fifth doped region 132a is coplanar with the bottom surface of the sixth doped region 132b. The difference D132 between the distance D5 and the distance D6 is zero.

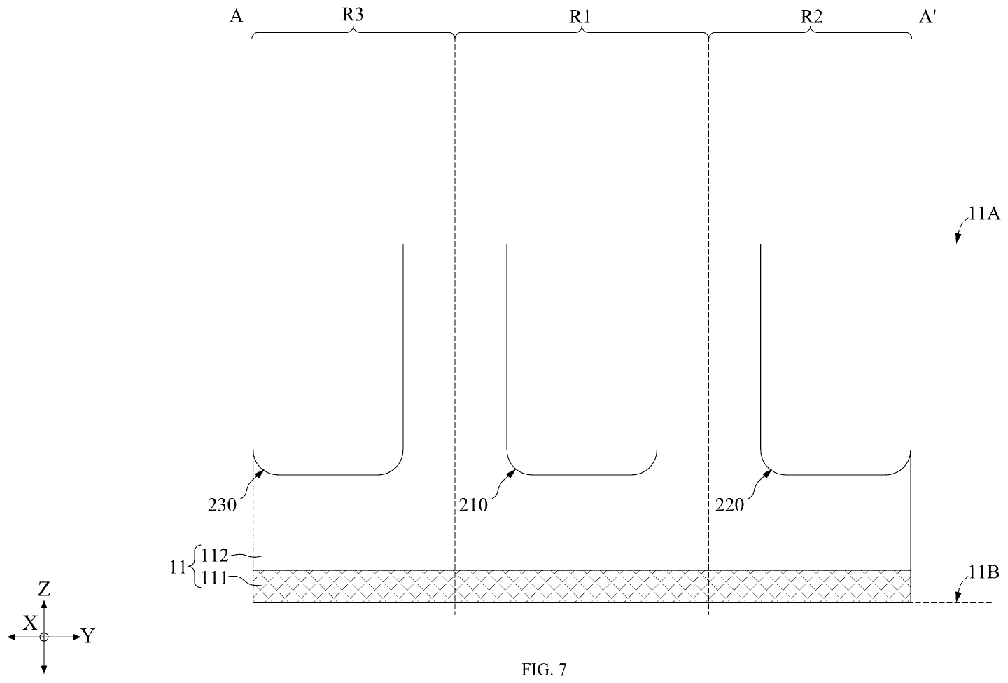

FIG. 7 to FIG. 30 illustrate examples of one or more stages in a manufacturing method of a trench semiconductor structure according to embodiments of the present disclosure. At least some of these drawings have been simplified to facilitate a better understanding of aspects of the present disclosure. The trench semiconductor structure formed by the manufacturing method may be similar to the trench semiconductor structure 10 described with respect to one of the embodiments above.

Referring to FIG. 7, a semiconductor material layer 11 may include a substrate 111 and an epitaxial layer 112 located on the substrate 111. The manufacturing method includes performing epitaxial growth on the substrate 111 to form the epitaxial layer 112. The epitaxial layer 112 has a first surface 11A of the semiconductor material layer 11, the substrate 111 has a second surface 11B of the semiconductor material layer 11, and the first surface 11A is opposite to the second surface 11B. The first surface 11A may be referred to as the top surface of the semiconductor material layer 11, and the second surface 11B may be referred to as the bottom surface of the semiconductor material layer 11. In some embodiments, ion implantation is performed simultaneously with the epitaxial growth, and ions with N-type electrical properties are implanted to form an N-type epitaxial layer 112.

A first patterned shielding layer (not shown) may be formed on the epitaxial layer 112 to define positions of a first trench 210, a second trench 220, and a third trench 230 as shown in FIG. 7. The first patterned shielding layer is used to perform an etching process (e.g., a plasma dry etching process) on the epitaxial layer 112 to form the first trench 210, the second trench 220, and the third trench 230 in the epitaxial layer 112 at intervals. Etching may be performed on the epitaxial layer 112 from the first surface 11A by using an etching process needle and stops in the epitaxial layer 112. According to the positions defined by the first patterned shielding layer, the first trench 210, the second trench 220, and the third trench 230 are formed at intervals in the semiconductor material layer 11 along the first direction X and extend from the first surface 11A toward the second surface 11B opposite to the first surface 11A. The first trench 210 is formed in a first region R1 of the semiconductor material layer 11, the second trench 220 is formed in a second region R2 of the semiconductor material layer 11, and the third trench 230 is formed in a third region R3 of the semiconductor material layer 11. The first region R1 is located between the second region R2 and the third region R3.

In some embodiments, the first trench 210, the second trench 220 and the third trench 230 may have vertical sidewalls. The first trench 210, the second trench 220 and the third trench 230 may have arc-shaped bottom surfaces. In addition, the first trench 210, the second trench 220 and the third trench 230 may be circular, elliptical, rectangular or polygonal. In some embodiments, the first trench 210, the second trench 220 and the third trench 230 have the same width. In some embodiments, the first trench 210, the second trench 220 and the third trench 230 have the same depth.

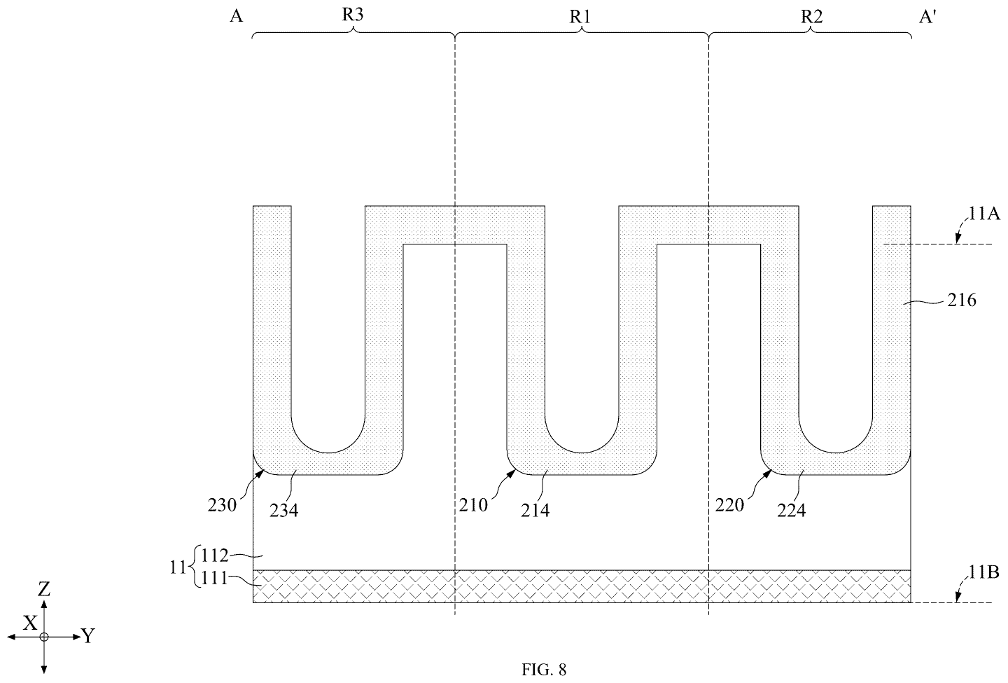

Referring to FIG. 8, the manufacturing method includes forming a first in-trench oxide layer 216 in the first trench 210, the second trench 220, and the third trench 230. In some embodiments, the first in-trench oxide layer 216 covers the first surface 11A. In some embodiments, the first in-trench oxide layer 216 may be formed by thermal oxidation technology or other deposition processes, such as atomic layer deposition (ALD), chemical vapor deposition (CVD), or other deposition methods. In some embodiments, the first in-trench oxide layer 216 may be conformally deposited on the inner side surfaces (including the opposite sidewalls and the bottom extending between the sidewalls) of the first trench 210, the second trench 220, and the third trench 230. In some embodiments, the first in-trench oxide layer 216 may be filled into the first trench 210, the second trench 220, and the third trench 230 through a deposition process, such that the first in-trench oxide layer 216 forms at least one groove in each of the first trench 210, the second trench 220, and the third trench 230. In some embodiments, a portion of the first in-trench oxide layer 216 formed in the first trench 210 is a first oxide layer 214, a portion of the first in-trench oxide layer 216 formed in the second trench 220 is a second oxide layer 224, and a portion of the first in-trench oxide layer 216 formed in the third trench 230 is a third oxide layer 234. The first oxide layer 214, the second oxide layer 224, and the third oxide layer 234 are formed simultaneously.

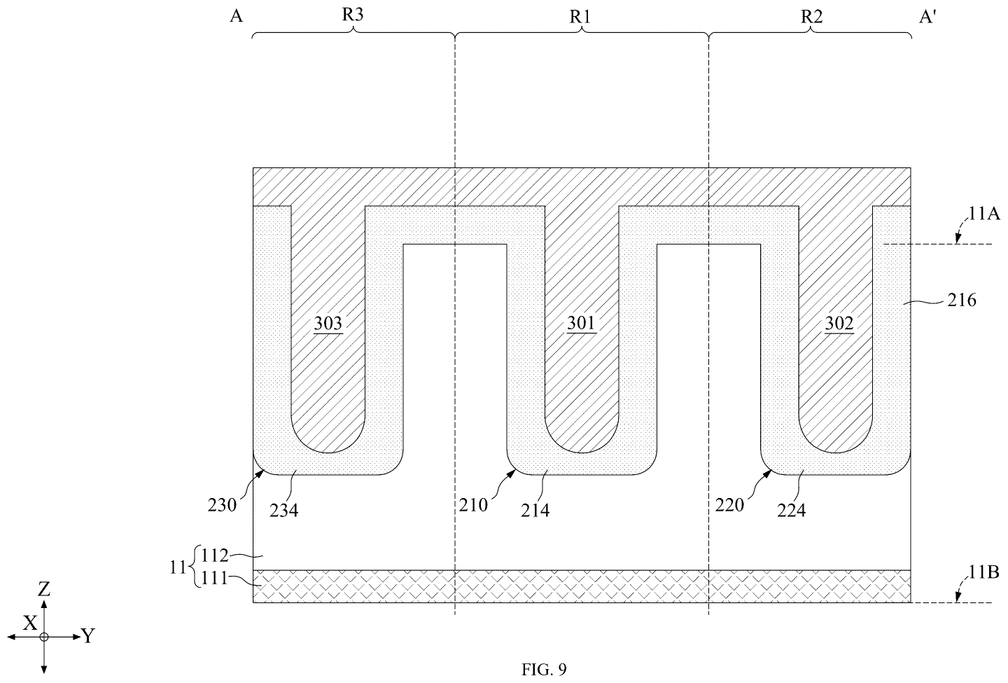

Referring to FIG. 9, the manufacturing method includes forming a first semiconductor material 301, a second semiconductor material 302, and a third semiconductor material 303 in the first trench 210, the second trench 220, and the third trench 230, respectively. In some embodiments, the first semiconductor material 301 is disposed in the first trench 210, the second semiconductor material 302 is disposed in the second trench 220, and the third semiconductor material 303 is disposed in the third trench 230.

The first in-trench oxide layer 216 may surround the first semiconductor material 301, the second semiconductor material 302, and the third semiconductor material 303. In some embodiments, the first semiconductor material 301, the second semiconductor material 302, and the third semiconductor material 303 may be formed by physical vapor deposition (PVD), such as sputtering or spraying of a semiconductor material. In some embodiments, the first semiconductor material 301, the second semiconductor material 302, and the third semiconductor material 303 may be formed by electroplating or CVD of a semiconductor material. In some embodiments, the first semiconductor material 301, the second semiconductor material 302, and the third semiconductor material 303 include polysilicon. In some embodiments, the semiconductor material covers the first in-trench oxide layer 216.

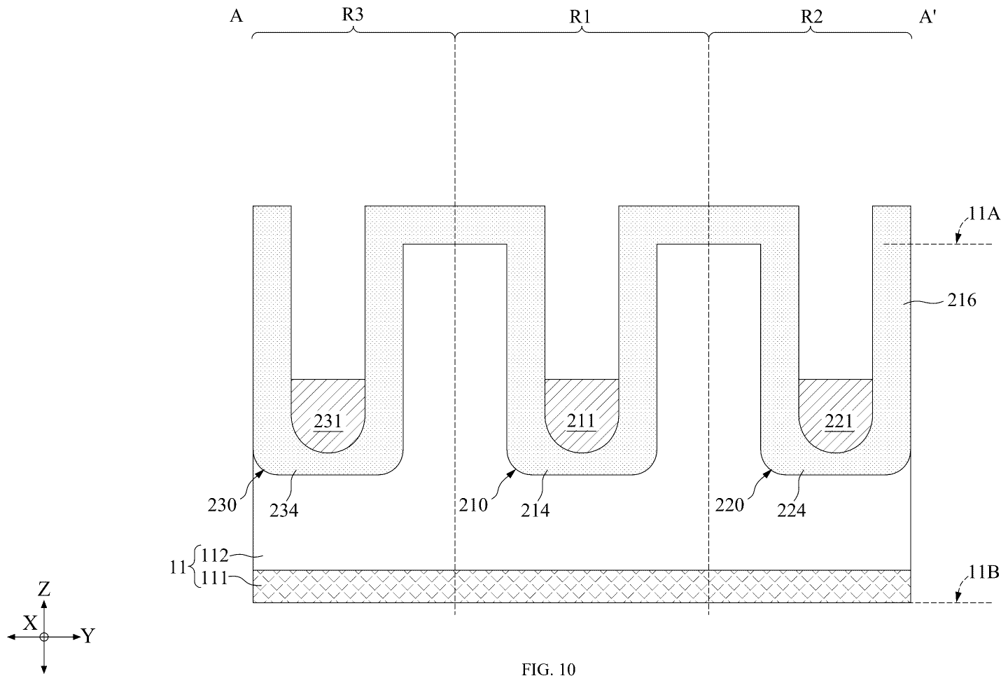

Referring to FIG. 10, the manufacturing method includes performing an etching process on the first semiconductor material 301, the second semiconductor material 302, and the third semiconductor material 303. The etching process is performed from the first surface 11A toward the second surface 11B to remove a first portion of the first semiconductor material 301, a first portion of the second semiconductor material 302, and a first portion of the third semiconductor material 303, and the etching process stops in the first trench 210, the second trench 220, and the third trench 230, such that part of the first in-trench oxide layer 216 is exposed, and a second portion of the first semiconductor material 301, a second portion of the second semiconductor material 302, and a second portion of the third semiconductor material 303 are retained. In some embodiments, the second portion of the first semiconductor material 301 forms a first electrode 211, the second portion of the second semiconductor material 302 forms a third electrode 221, and the second portion of the third semiconductor material 303 forms a fourth electrode 231. The first oxide layer 214, the second oxide layer 224, and the third oxide layer 234 respectively have vertical sidewalls, which are exposed after etching.

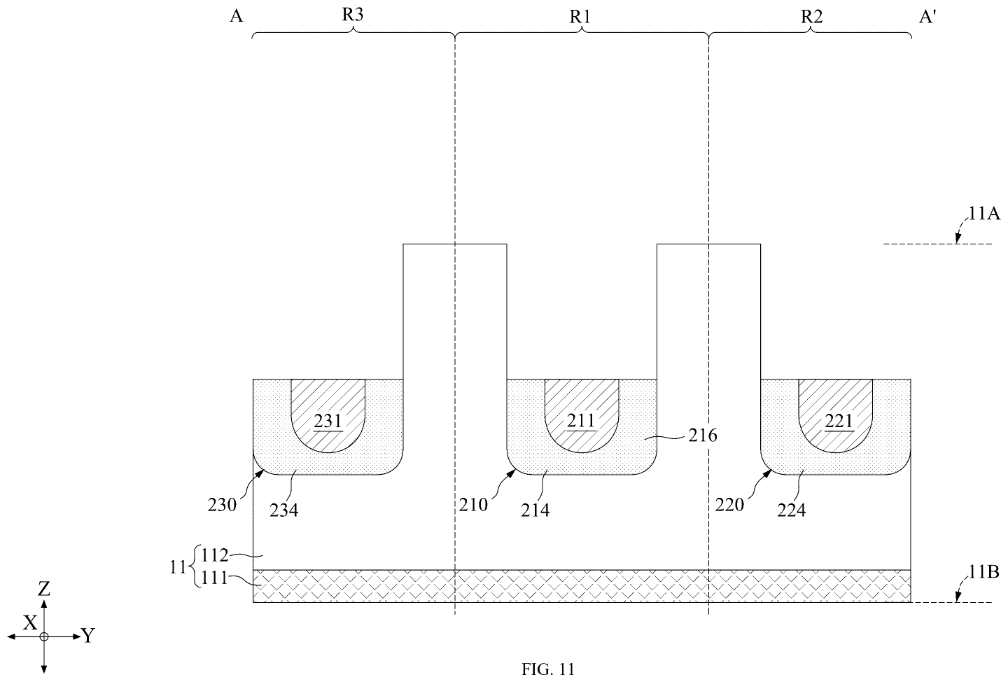

Referring to FIG. 11, the manufacturing method includes removing the first in-trench oxide layer 216 that covers the first surface 11A and portions of the inner side surfaces of the first trench 210, the second trench 220, and the third trench 230, such that a portion of the inner side surfaces of the first trench 210, a portion of the inner side surfaces of the second trench 220, and a portion of the inner surfaces of the third trench 230 (including the opposite sidewalls) are exposed. The first in-trench oxide layer 216 may be removed by an etching method. In some embodiments, the manufacturing method includes removing the first in-trench oxide layer 216 located in the first region R1, the second region R2, and the third region R3, such that a portion of the epitaxial layer 112 is exposed, while the first oxide layer 214, the second oxide layer 224, and the third oxide layer 234 located respectively at the bottom of the first trench 210, the second trench 220, and the third trench 230 are retained. The manufacturing method does not remove the first in-trench oxide layer 216 surrounding the first electrode 211, the third electrode 221 and the fourth electrode 231. The manufacturing method may cause the first oxide layer 214 to be coplanar with the top surface of the first electrode 211, the second oxide layer 224 to be coplanar with the top surface of the third electrode 221, and the third oxide layer 234 to be coplanar with the top surface of the fourth electrode 231. The top surface of the first electrode 211, the top surface of the third electrode 221, and the top surface of the fourth electrode 231 are exposed.

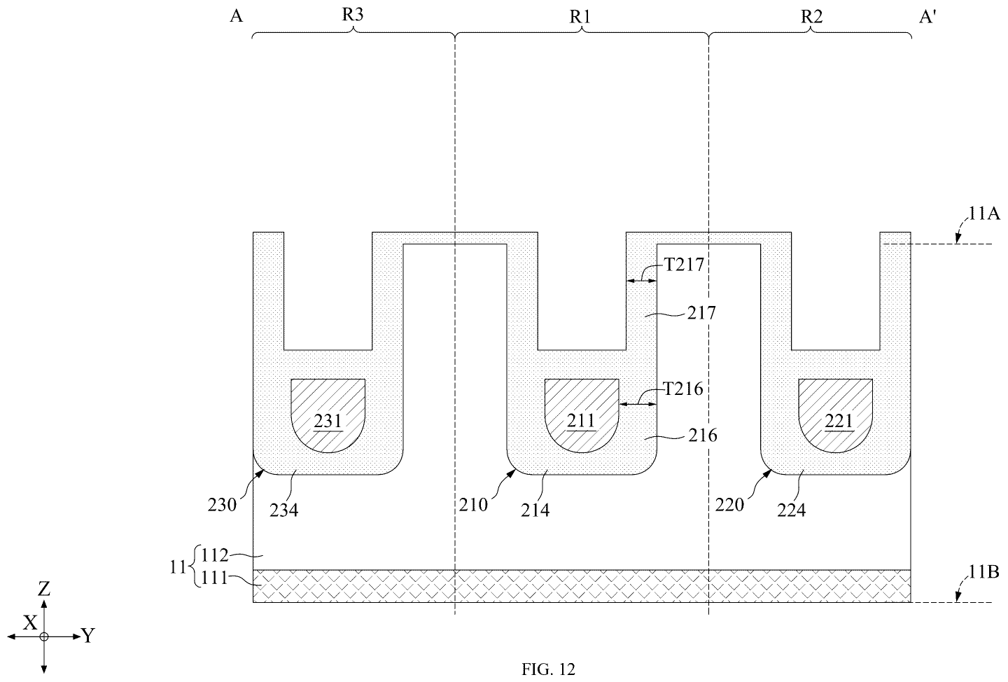

Referring to FIG. 12, the manufacturing method includes forming a second in-trench oxide layer 217 in the first trench 210, the second trench 220 and the third trench 230, on the first electrode 211, the third electrode 221 and the fourth electrode 231, and on the exposed epitaxial layer 112. The second in-trench oxide layer 217 is formed in the first region R1, the second region R2, and the third region R3. In some embodiments, the second in-trench oxide layer 217 covers the first surface 11A. In some embodiments, the second in-trench oxide layer 217 may be formed by thermal oxidation technology or other deposition processes. In some embodiments, the second in-trench oxide layer 217 may be conformally deposited on the inner side surfaces (including the opposite sidewalls) of the first trench 210, the second trench 220 and the third trench 230, and on the first oxide layer 214, the second oxide layer 224, the third oxide layer 234, the first electrode 211, the third electrode 221 and the fourth electrode 231.

The second in-trench oxide layer 217 may be filled into the first trench 210, the second trench 220, and the third trench 230 through a deposition process, such that the second in-trench oxide layer 217 forms at least one groove respectively above the first electrode 211 in the first trench 210, the third electrode 221 in the second trench 220, and the fourth electrode 231 in the third trench 230. In some embodiments, the portion of the second in-trench oxide layer 217 in the first trench 210 is the first oxide layer 214, the portion in the second trench 220 is the second oxide layer 224, and the portion in the third trench 230 is the third oxide layer 234. That is, the portion of the second in-trench oxide layer 217 in the first trench 210 and the portion of the first in-trench oxide layer 216 in the first trench 210 constitutes the first oxide layer 214 in the first trench 210. Similarly, the portion of the second in-trench oxide layer 217 in the second trench 220 and the portion of the first in-trench oxide layer 216 in the second trench 220 constitutes the second oxide layer 224 in the second trench 220. The portion of the second in-trench oxide layer 217 in the third trench 230 and the portion of the first in-trench oxide layer 216 in the third trench 230 constitutes the third oxide layer 234 in the third trench 230. In some embodiments, the thickness T217 of the second in-trench oxide layer 217 (on the sidewalls of the trenches 210, 2220 and 230) is less than or equal to the thickness T216 of the first in-trench oxide layer 216.

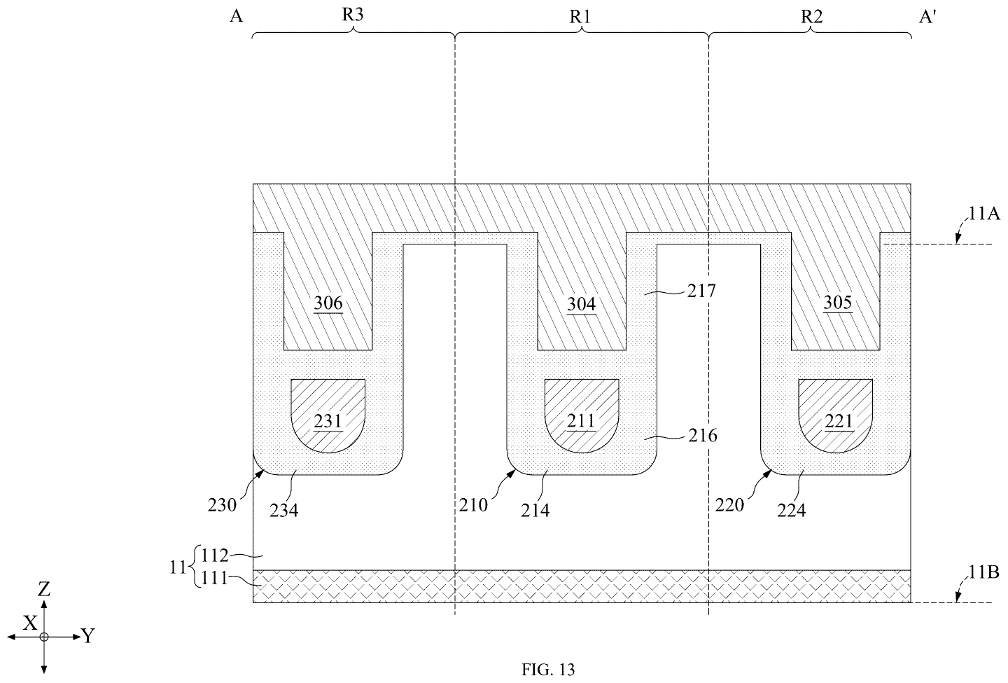

Referring to FIG. 13, the manufacturing method includes forming a fourth semiconductor material 304, a fifth semiconductor material 305, and a sixth semiconductor material 306 in the first trench 210, the second trench 220, and the third trench 230, respectively. In some embodiments, the fourth semiconductor material 304 is disposed in the first trench 210 and on the top surface of the first oxide layer 214, the fifth semiconductor material 305 is disposed in the second trench 220 and on the top surface of the second oxide layer 224, and the sixth semiconductor material 306 is disposed in the third trench 230 and on the top surface of the third oxide layer 234.

The second in-trench oxide layer 217 may surround the fourth semiconductor material 304, the fifth semiconductor material 305, and the sixth semiconductor material 306. In some embodiments, the fourth semiconductor material 304, the fifth semiconductor material 305, and the sixth semiconductor material 306 may be formed by physical vapor deposition (PVD), such as sputtering or spraying of a semiconductor material. In some embodiments, the fourth semiconductor material 304, the fifth semiconductor material 305, and the sixth semiconductor material 306 may be formed by electroplating or CVD of a semiconductor material. In some embodiments, the fourth semiconductor material 304, the fifth semiconductor material 305, and the sixth semiconductor material 306 include polysilicon. In some embodiments, the semiconductor material covers the second in-trench oxide layer 217. The fourth semiconductor material 304, the fifth semiconductor material 305, and the sixth semiconductor material 306 covers the second in-trench oxide layer 217 in the first trench 210, the second trench 220, and the third trench 230, respectively, and also covers the second in-trench oxide layer 217 on the first surface 11A.

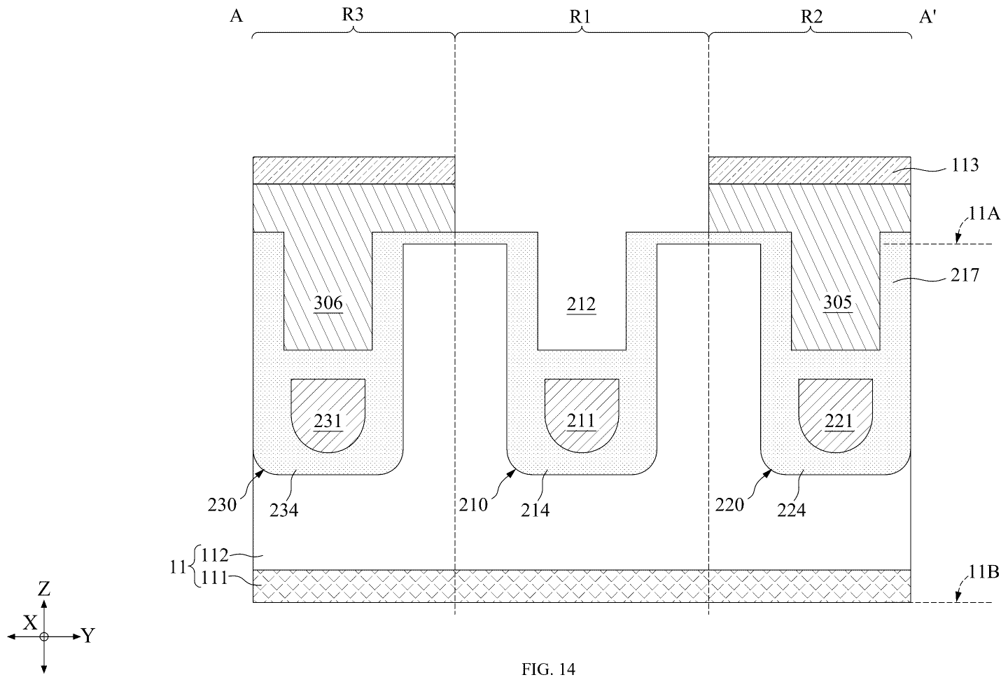

Referring to FIG. 14, the manufacturing method includes forming a second patterned shielding layer 113 as shown in FIG. 14 on the fifth semiconductor material 305 in the second region R2 and the sixth semiconductor material 306 in the third region R3, and FIG. 14 shows that stage of the manufacturing method after performing an etching process on the fourth semiconductor material 304 (as shown in FIG. 13) through the second patterned shielding layer 113. The etching process removes the fourth semiconductor material 304, and the etching stops at the second in-trench oxide layer 217 and the first oxide layer 214, and exposes a portion of the second in-trench oxide layer 217 and the first oxide layer 214 in the first trench 210. The etching removes the fourth semiconductor material 304 covering the second in-trench oxide layer 217 in the first trench 210 and in the first region R1, and as a result, portions of the second in-trench oxide layer 217 in the first region R1, that is, a portion of the second in-trench oxide layer 217 on the first surface 11A and a portion of the second in-trench oxide layer 217 in the first trench 210 (i.e., a portion of the first oxide layer 214) are exposed. According to the position defined by the second patterned shielding layer 113, the fifth semiconductor material 305 in the second region R2 and the sixth semiconductor material 306 located in the third region R3 are retained. In some embodiments, after removing the fourth semiconductor material 304, the fifth semiconductor material 305 and the sixth semiconductor material 306 each have vertical sidewalls on the second in-trench oxide layer 217. In some embodiments, the second patterned shielding layer 113 is formed by performing a photolithography process using a photomask having a corresponding pattern.

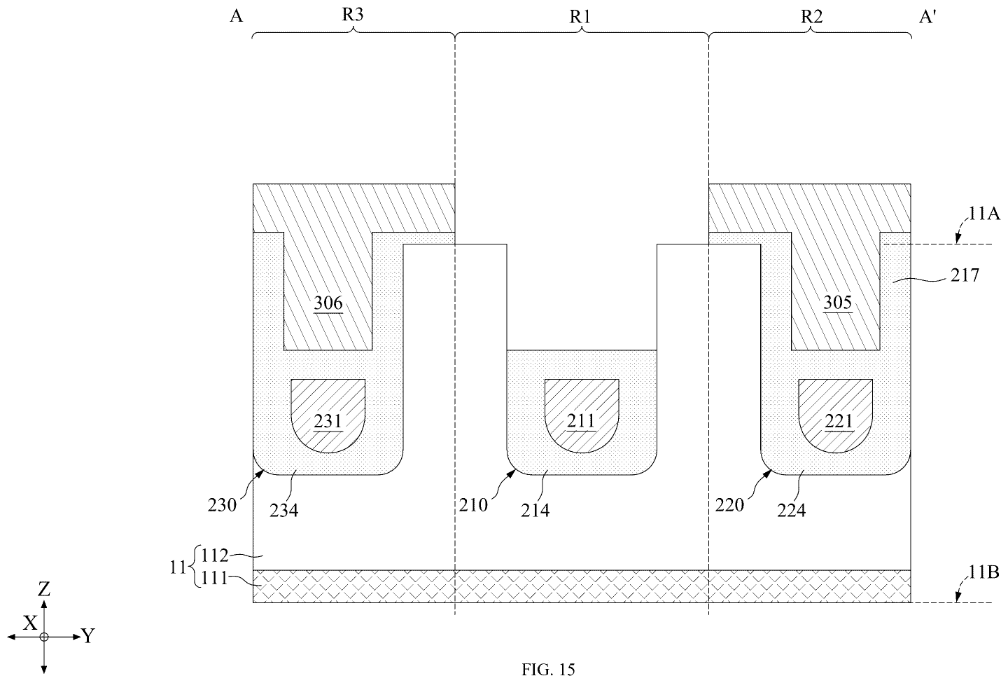

Referring to FIG. 15, in some embodiments, the manufacturing method includes removing the second in-trench oxide layer 217 that is located in the first region R1 and covers the first surface 11A and the inner side surfaces of the first trench 210, such that a portion of the epitaxial layer 112 and a portion of the inner side surfaces of the first trench 210 (including the opposite sidewalls) are exposed, while the first oxide layer 214 located at the bottom of the first trench 210 is retained. The second in-trench oxide layer 217 located in the first region RI may be removed by etching. In some embodiments, the manufacturing method includes removing the second in-trench oxide layer 217 that is not in contact with the fifth semiconductor material 305 and the sixth semiconductor material 306. The manufacturing method may also include removing the second patterned shielding layer 113, so that the top surface of the fifth semiconductor material 305 and the top surface of the sixth semiconductor material 306 are exposed.

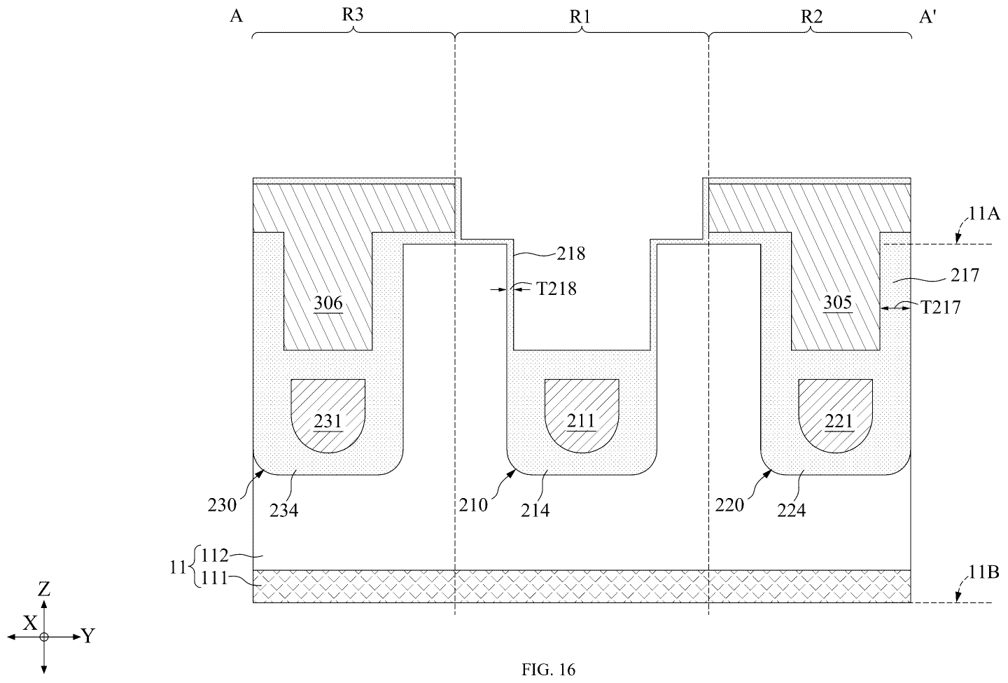

Referring to FIG. 16, the manufacturing method includes forming a third in-trench oxide layer 218 on the epitaxial layer 112 exposed in the first region R1 and on the top surfaces and sidewalls of the fifth semiconductor material 305 and the sixth semiconductor material 306 located in the second region R2 and the third region R3 respectively. At least a portion of the third in-trench oxide layer 218 is located in the first trench 210. The third in-trench oxide layer 218 is formed in the first region R1, the second region R2, and the third region R3. In some embodiments, the third in-trench oxide layer 218 covers the first surface 11A that is exposed. In some embodiments, the third in-trench oxide layer 218 may be formed by thermal oxidation technology or other deposition processes. In some embodiments, the third in-trench oxide layer 218 may be conformally deposited on the inner side surfaces (including the opposite sidewalls) of the first trench 210 and the top surfaces and sidewalls of the fifth semiconductor material 305 and the sixth semiconductor material 306. In some embodiments, the third in-trench oxide layer 218 is used as a sacrificial structure and will be removed in a subsequent step such that the surface exposed after the third in-trench oxide layer 218 is removed has better quality, e.g., the exposed surface is smoother, which is conducive to forming other structures on the exposed surface.

In some embodiments, the third in-trench oxide layer 218 may be filled into the first trench 210 through a deposition process, such that the third in-trench oxide layer 218 covers and surrounds the fifth semiconductor material 305 and the sixth semiconductor material 306, and forms a recess on the first oxide layer 214 in the first trench 210. In some embodiments, the thickness T218 of the third in-trench oxide layer 218 is less than the thickness T217 of the second in-trench oxide layer 217.

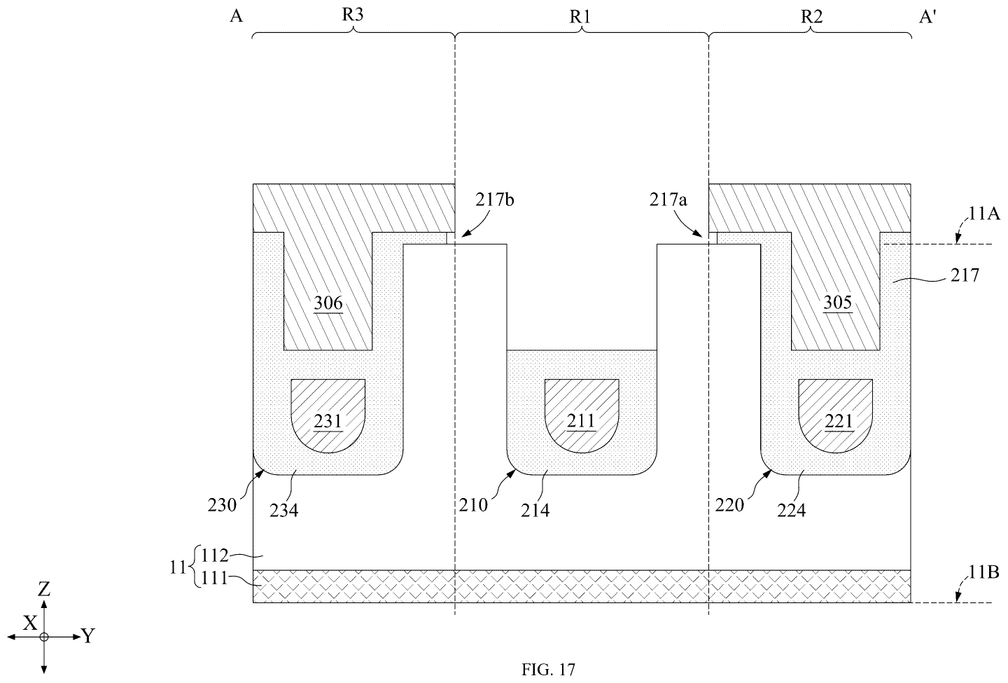

Referring to FIG. 17, the manufacturing method includes removing the third in-trench oxide layer 218. The manufacturing method includes removing the third in-trench oxide layer 218 located in the first region R1, the second region R2, and the third region R3, that is, removing the third in-trench oxide layer 218 that covers the top surfaces and sidewalls of the fifth semiconductor material 305 and the sixth semiconductor material 306 and that is located on the inner side surfaces of the first trench 210 and on the first surface 11A, such that the epitaxial layer 112 in the first region R1, part of the inner side surfaces of the first trench 210 (including the opposite sidewalls), and the fifth semiconductor material 305 and the sixth semiconductor material 306 are exposed. The third in-trench oxide layer 218 may be removed by etching. The epitaxial layer 112 exposed by removing the third in-trench oxide layer 218 has a relatively flat surface flatness. In some embodiments, the stages shown in FIGS. 16 and 17 may be omitted.

In some embodiments, the manufacturing method further includes forming a side cut 217a in the second in-trench oxide layer 217 located in the second region R2, and the side cut 217a is formed on the first surface 11A and extends from the first region R1 to the second region R2. In a top view, the side cut 217a overlaps with the fifth semiconductor material 305. That is, a first portion of the second in-trench oxide layer 217 covering the first surface 11A in the second region R2 is removed to form the side cut 217a, where the first portion of the second in-trench oxide layer 217 is in the second region R2 between the first surface 11A and the fifth semiconductor material 305 and adjoins the first region R1. The manufacturing method further includes forming a side cut 217b in the second in-trench oxide layer 217 located in the third region R3, and the side cut 217b is formed on the first surface 11A and extends from the first region R1 to the third region R3. In the top view, the side cut 217b overlaps with the sixth semiconductor material 306. That is, a second portion of the second in-trench oxide layer 217 in the third region R3 covering the first surface 11A is removed to form the side cut 217b, where the second portion of the second in-trench oxide layer 217 is in the third region R3 between the first surface 11A and the sixth semiconductor material 306 and adjoins the first region R1. In some embodiments, the side cut 217a and the side cut 217b surround the first trench 210, in the top view.

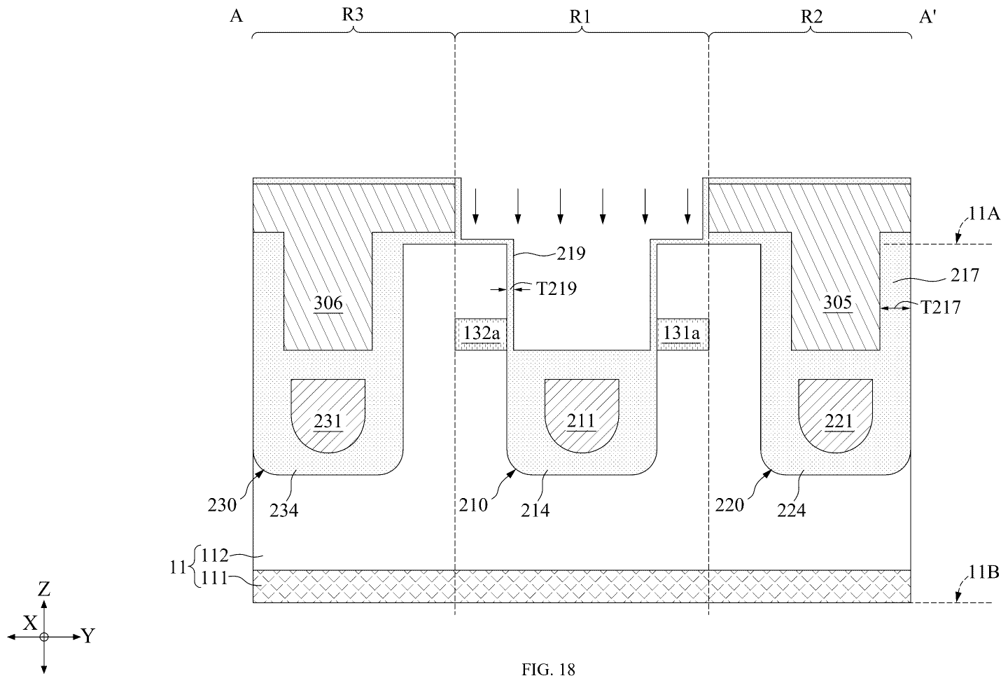

Referring to FIG. 18, the manufacturing method includes forming a fourth in-trench oxide layer 219 on the epitaxial layer 112 exposed in the first region R1 and on the top surfaces and sidewalls of the fifth semiconductor material 305 and the sixth semiconductor material 306 located in the second region R2 and the third region R3. At least a portion of the fourth in-trench oxide layer 219 is located in the first trench 210. The fourth in-trench oxide layer 219 is formed in the first region R1, the second region R2, and the third region R3. In some embodiments, the fourth in-trench oxide layer 219 covers the first surface 11A. In some embodiments, the fourth in-trench oxide layer 219 may be formed by thermal oxidation technology or other deposition processes. In some embodiments, the fourth in-trench oxide layer 219 may be conformally deposited on the inner side surfaces (including the opposite sidewalls) of the first trench 210 and the top surfaces and sidewalls of the fifth semiconductor material 305 and the sixth semiconductor material 306.

In some embodiments, the fourth in-trench oxide layer 219 may be filled into the first trench 210 through a deposition process, such that the fourth in-trench oxide layer 219 covers and surrounds the fifth semiconductor material 305 and the sixth semiconductor material 306, and forms a groove with the first oxide layer 214 in the first trench 210. The groove is above the first electrode 211 and separated from the first electrode 211 by the first oxide layer 214. The groove is surrounded by the fourth in-trench oxide layer 219 on the inner side surfaces of the first trench 210. In some embodiments, the portion of the fourth in-trench oxide layer 219 in the first trench 210 and the previously formed first oxide layer 214 is collectively referred to as the first oxide layer 214 in the first trench 210. In some embodiments, the thickness T219 of the fourth in-trench oxide layer 219 is less than the thickness T217 of the second in-trench oxide layer 217.

Referring again to FIG. 18, the manufacturing method further includes forming a first doped region 131a and a fifth doped region 132a in the epitaxial layer 112 of the first region R1. The first doped region 131a and the fifth doped region 132a are formed below the fourth in-trench oxide layer 219. The first doped region 131a is located between the first trench 210 and the second trench 220 and away from the first surface 11A, and the first doped region 131a has the second conductivity type and contacts the first oxide layer 214. The fifth doped region 132a is located between the first trench 210 and the third trench 230 and away from the first surface 11A, and the fifth doped region 132a has the second conductivity type and contacts the first oxide layer 214. The first doped region 131a and the fifth doped region 132a may be formed simultaneously and have the same depth. The first doped region 131a and the fifth doped region 132a are formed at two outer sides of the first trench 210 and in contact with the first oxide layer 214. A portion of the epitaxial layer 112 is between the first doped region 131a and the first surface 11A, and another portion of the epitaxial layer 112 is between the fifth doped region 132a and the first surface 11A.

The first doped region 131a and the fifth doped region 132a may be formed in the epitaxial layer 112 by diffusion or ion implantation from the first surface 11A, and ions are implanted into the first surface 11A along the vertical direction Z. The first doped region 131a and the fifth doped region 132a are formed in the first region R1, and the depth of the first doped region 131a and the depth of the fifth doped region 132a are respectively less than the depth of the first trench 210. In other words, the bottom of the first doped region 131a and the bottom of the fifth doped region 132a are higher than the bottom of the first trench 210. In some embodiments, the bottom of the first doped region 131a and the bottom of the fifth doped region 132a are higher than the first electrode 211.

In some embodiments, an annealing process may be performed after the first doped region 131a and the fifth doped region 132a are formed by the ion implantation process, to diffuse the doping ions. In some embodiments, the doping ions may be, for example, boron ions, aluminum ions, gallium ions, indium ions, etc. In some embodiments, boron ions are implanted into the first doped region 131a and the fifth doped region 132a.

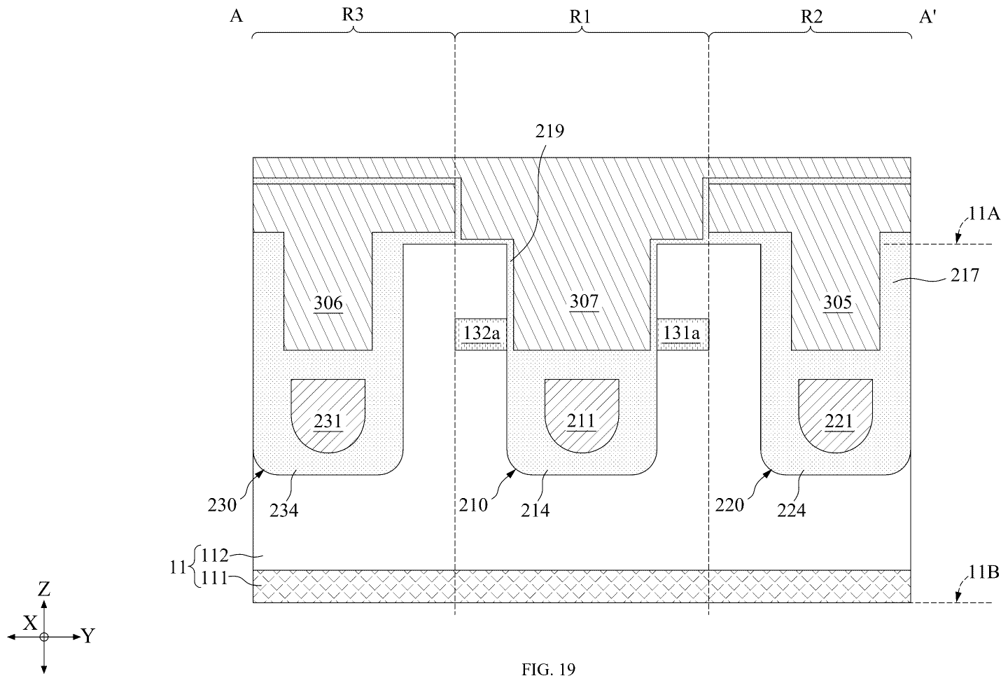

Referring to FIG. 19, the manufacturing method includes forming a seventh semiconductor material 307 on the fourth in-trench oxide layer 219. In some embodiments, the seventh semiconductor material 307 is formed in the first trench 210 and above the fifth semiconductor material 305 and the sixth semiconductor material 306, and covers the fourth in-trench oxide layer 219. The seventh semiconductor material 307 contacts the fourth in-trench oxide layer 219 and the first oxide layer 214.

In some embodiments, the seventh semiconductor material 307 disposed in the first trench 210 is located above the first electrode 211 and is surrounded by the fourth in-trench oxide layer 219, and the seventh semiconductor material 307 is also located above the fifth semiconductor material 305 and the sixth semiconductor material 306. A portion of the fourth in-trench oxide layer 219 is located between the seventh semiconductor material 307 and the fifth semiconductor material 305, a portion of the fourth in-trench oxide layer 219 is located between the seventh semiconductor material 307 and the sixth semiconductor material 306, and a portion of the fourth in-trench oxide layer 219 is located between the seventh semiconductor material 307 and the epitaxial layer 112. The fourth in-trench oxide layer 219 surrounds the seventh semiconductor material 307 in the first trench 210.

In some embodiments, the seventh semiconductor material 307 may be formed by PVD, such as sputtering or spraying of a semiconductor material. In some embodiments, the seventh semiconductor material 307 may be formed by electroplating or CVD of a semiconductor material. In some embodiments, the seventh semiconductor material 307 includes polysilicon. In some embodiments, the seventh semiconductor material 307 includes the same material as or a different material from the fifth semiconductor material 305 and the sixth semiconductor material 306.

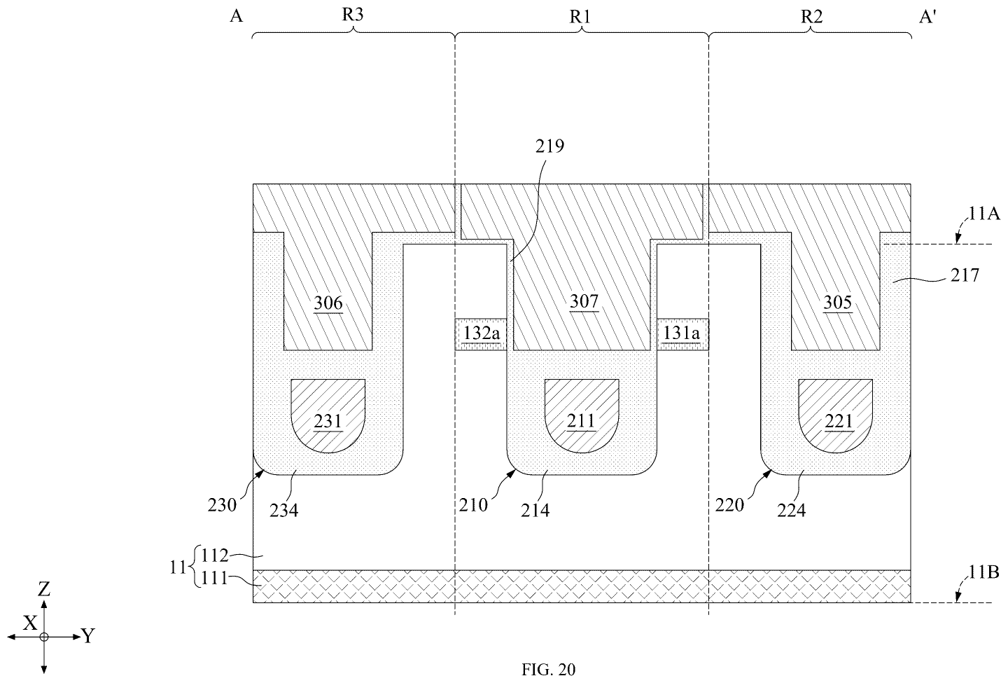

Referring to FIG. 20, the manufacturing method includes removing a portion of the seventh semiconductor material 307 and the fourth in-trench oxide layer 219 on the fifth semiconductor material 305 and the sixth semiconductor material 306 to expose the fifth semiconductor material 305 and the sixth semiconductor material 306. The fourth in-trench oxide layer 219 on the fifth semiconductor material 305 and the sixth semiconductor material 306, and the seventh semiconductor material 307 may be polished, for example, by a chemical-mechanical polishing (CMP) process. In some embodiments, the top surface of the seventh semiconductor material 307 is coplanar with the top surface of the fifth semiconductor material 305 and the top surface of the sixth semiconductor material 306. That is, a portion of the seventh semiconductor material 307 and a portion of the fourth in-trench oxide layer 219 that are above a surface coplanar with the top surfaces of the fifth semiconductor material 305 and the sixth semiconductor material 306 are removed, e.g. by polishing.

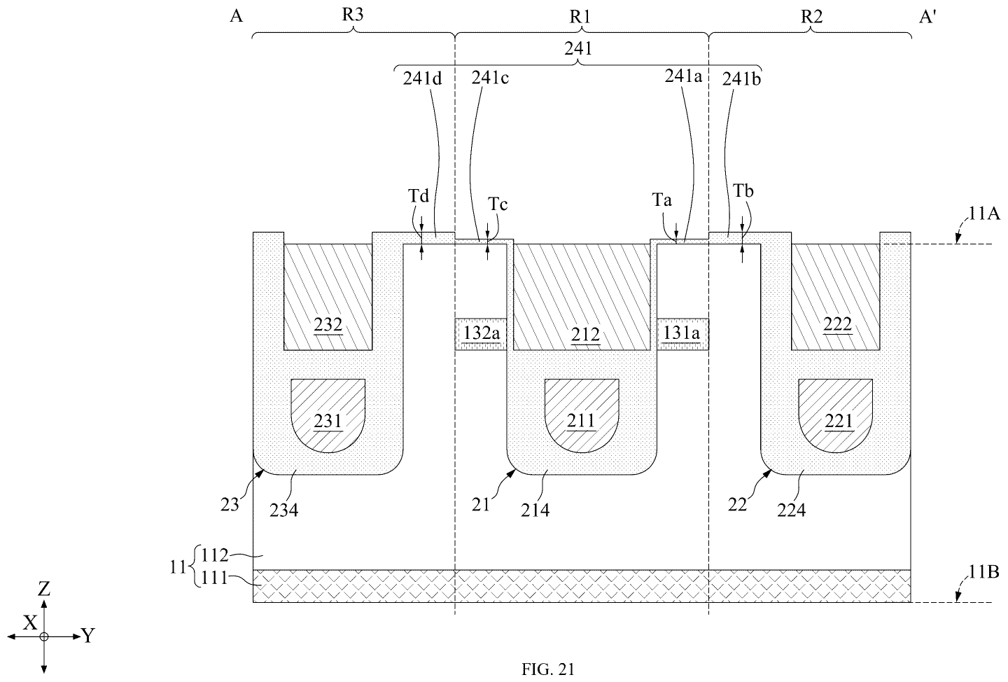

Referring to FIG. 21, the manufacturing method includes removing portions of the fifth semiconductor material 305, the sixth semiconductor material 306 and the seventh semiconductor material 307 that are above the first surface 11A of the semiconductor material layer 11. The manufacturing method also includes removing portions of the fourth in-trench oxide layer 219 on the first surface 11A, such that a remaining portion of the fourth in-trench oxide layer 219 on the first surface 11A above the first doped region 131a has a uniform thickness, and a remaining portion of the fourth in-trench oxide layer 219 on the first surface 11A above the fifth doped region 131a has a uniform thickness. As a result, the remaining portion of the seventh semiconductor material 307 located in the first trench 210 forms a second electrode 212, the remaining portion of the fifth semiconductor material 305 located in the second trench 220 forms a first gate 222, and the remaining portion of the sixth semiconductor material 306 located in the third trench 230 forms a second gate 232, and the fourth in-trench oxide layer 219 on the first surface 11A and portions of the second in-trench oxide layer 217 on the first surface 11A form a fourth oxide layer 241.

The fourth oxide layer 241 includes a first region 241a and a second region 241b. The first region 241a is located above the first doped region 131a of the first region R1, and the second region 241b is located in the second region R2. Since the thickness T219 of the fourth in-trench oxide layer 219 is less than the thickness T217 of the second in-trench oxide layer 217, the thickness Ta of the first region 241a is less than the thickness Tb of the second region 241b. The fourth oxide layer 241 also includes a third region 241c and a fourth region 241d. The third region 241c is located above the fifth doped region 132a of the first region R1, and the fourth region 241d is located in the third region R3. Since the thickness T219 of the fourth in-trench oxide layer 219 is less than the thickness T217 of the second in-trench oxide layer 217, the thickness Tc of the third region 241c is less than the thickness Td of the fourth region 241d. In some embodiments, the thickness Ta and Tc may be the same as the thickness T219 of the fourth in-trench oxide layer 219, and the thickness Tb and Td may be the same as the thickness T217 of the second in-trench oxide layer 217.

The second electrode 212, the first gate 222, and the second gate 232 may be formed simultaneously. In some embodiments, after the second electrode 212 is formed in the first trench 210, the first electrode 211, the second electrode 212 located above the first electrode 211, and the first oxide layer 214 surrounding the first electrode 211 and the second electrode 212 and separating the two, form a first trench structure 21. After the first gate 222 is formed in the second trench 220, the first gate 222, the third electrode 221 located below the first gate 222, and the second oxide layer 224 surrounding the third electrode 221 and the first gate 222 and separating the two, form a second trench structure 22. In some embodiments, after the second gate 232 is formed in the third trench 230, the second gate 232 is located above the fourth electrode 231, and the second gate 232, the fourth electrode 231, and the third oxide layer 234 surrounding and separating the fourth electrode 231 and the fourth electrode 231 form a third trench structure 23. In some embodiments, the first trench structure 21, the second trench structure 22, and the third trench structure 23 are formed simultaneously. In some embodiments, the second trench structure 22 is formed before the first trench structure 21, or the third trench structure 23 is formed before the first trench structure 21.

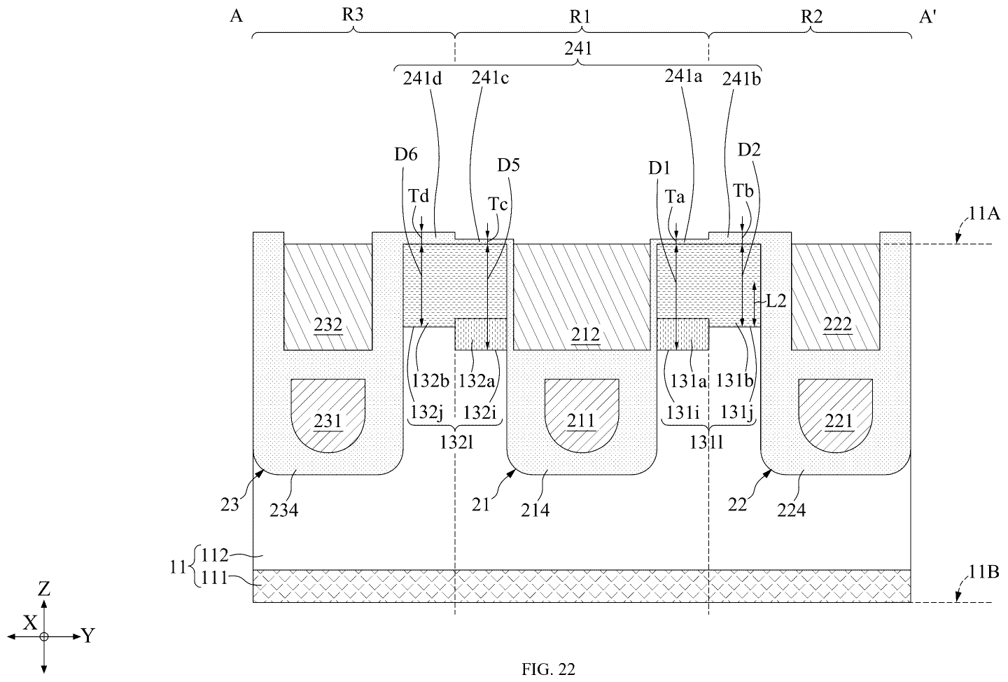

Referring to FIG. 22, the manufacturing method includes forming a second doped region 131b in the semiconductor material layer 11 between the first trench structure 21 and the second trench structure 22, and forming a sixth doped region 132b in the semiconductor material layer 11 between the first trench structure 21 and the third trench structure 23.

The second doped region 131b and the sixth doped region 132b have the second conductivity type. The second doped region 131b and the sixth doped region 132b may be formed in the epitaxial layer 112 by diffusion or ion implantation from the first surface 11A. Ions may be implanted into the first surface 11A along the vertical direction Z through the fourth oxide layer 241, and may also be implanted into the epitaxial layer 112 between the first doped region 131a and the first surface 11A and the epitaxial layer 112 between the fifth doped region 132a and the first surface 11A. The second doped region 131b is formed between the first doped region 131a and the first surface 11A and is connected to the first doped region 131a. The second doped region 131b and the first doped region 131a constitute a first doped block 131. As described above, the first doped block 131 has a border line (the first boundary) 1311 defining the region of the first doped block 131 in the epitaxial layer 112. The first boundary 1311 includes a first portion 131i that is the bottom surface of the first doped region 131a and a second portion 131j that is the bottom surface of the second doped region 131b. In some embodiments, the depth of the second doped region 131b may be measured as the distance between the second portion 131j and the first surface 11A, i.e., the distance D2. The sixth doped region 132b is formed between the fifth doped region 132a and the first surface 11A and is connected to the fifth doped region 132a. The sixth doped region 132b and the fifth doped region 132a constitute a third doped block 132. As described above, the third doped block 132 has a border line (the third boundary) 1321 defining the region of the third doped block 132 in the epitaxial layer 112. The third boundary 1321 includes a fifth portion 132i that is the bottom surface of the fifth doped region 132a and a sixth portion 132j that is the bottom surface of the sixth doped region 132b. In some embodiments, the depth of the sixth doped region 132b may be measured as the distance between the sixth portion 132j and the first surface 11A, i.e., the distance D6.

In some embodiments, an annealing process may be performed after the second doped region 131b and the sixth doped region 132b are formed by the ion implantation process, to diffuse the doping ions. In some embodiments, the doping ions are, for example, boron ions, aluminum ions, gallium ions, indium ions, etc. In some embodiments, boron ions are implanted into the second doped region 131b and the sixth doped region 132b.

The depth of the second doped region 131b may be adjusted according to the position of the first doped region 131a. In some embodiments, the depth of the second doped region 131b is less than the depth of the first doped region 131a. The distance D1 between the bottom surface of the first doped region 131a and the first surface 11A is greater than the distance D2 between the bottom surface of the second doped region 131b and the first surface 11A. In some embodiments, the second doped region 131b diffuses to the first region R1. Since the thickness Ta of the first region 241a of the fourth oxide layer 241 is less than the thickness Tb of the second region 241b, the depth of the second doped region 131b in the first region R1 is greater than the depth of the second doped region 131b in the second region R2.

The depth of the sixth doped region 132b may be adjusted according to the position of the fifth doped region 132a. In some embodiments, the depth of the sixth doped region 132b is less than the depth of the fifth doped region 132a. The distance D5 between the bottom surface of the fifth doped region 132a and the first surface 11A is greater than the distance D6 between the bottom surface of the sixth doped region 132b and the first surface 11A. In some embodiments, the sixth doped region 132b diffuses to the first region R1. Since the thickness Tc of the third region 241c of the fourth oxide layer 241 is less than the thickness Td of the fourth region 241d, the depth of the sixth doped region 132b in the first region R1 is greater than the depth of the sixth doped region 132b in the third region R3.

As shown, in this example, the second doped region 131b may include a first portion in the first region R1 and a second portion in the second region R2. The first portion of the second doped region 131b is between the first doped region 131a and the first surface 11A, and in contact with the first oxide layer 214 and the first doped region 131a. The second portion of the second doped region 131b is between the first surface 11A and the second portion 131j of the first boundary 1311, and in contact with the second oxide layer 224 and the first doped region 131a.

The sixth doped region 132b may include a first portion in the first region R1 and a second portion in the third region R3. The first portion of the sixth doped region 132b is between the fifth doped region 132a and the first surface 11A, and in contact with the first oxide layer 214 and the fifth doped region 132a. The second portion of the sixth doped region 132b is between the first surface 11A and the second portion 132j of the third boundary 1321, and in contact with the third oxide layer 234 and the fifth doped region 132a.

In some embodiments, before forming the second doped region 131b and the sixth doped region 132b, the fourth oxide layer 241 is formed. In some embodiments, a third patterned shielding layer (not shown) is formed on the fourth oxide layer 241 to define the positions of the second doped region 131b and the sixth doped region 132b. The conductivity types and depths of the second doped region 131b and the sixth doped region 132b may be defined by adjusting the ions, energy and dose of the diffusion or ion implantation process. In some embodiments, the third patterned shielding layer may be formed by performing a photolithography process using a photomask having a corresponding pattern.

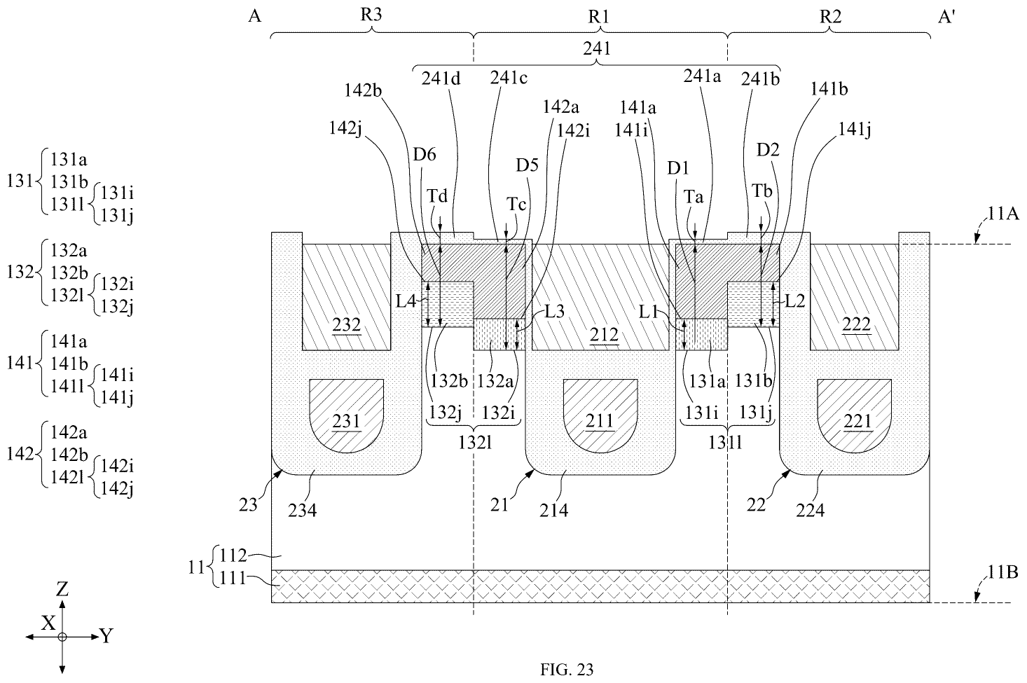

Referring to FIG. 23, the manufacturing method includes forming a third doped region 141a and a fourth doped region 141b in the semiconductor material layer 11 between the first trench structure 21 and the second trench structure 22, and forming a seventh doped region 142a and an eighth doped region 142b in the semiconductor material layer 11 between the first trench structure 21 and the third trench structure 23. The third doped region 141a is in the semiconductor material layer 11 and is located between the first surface 11A and the first doped region 131a. The fourth doped region 141b is in the semiconductor material layer 11, and is located between the first surface 11A and the second doped region 131b. The third doped region 141a and the fourth doped region 141b have the first conductivity type.

The third doped region 141a and the fourth doped region 141b may be formed in the epitaxial layer 112 by diffusion or ion implantation from the first surface 11A, and ions are implanted into the first surface 11A along the vertical direction Z. The third doped region 141a is formed in the first region R1, and the fourth doped region 141b is formed in the second region R2. The depths of the third doped region 141a and the fourth doped region 141b are respectively less than the depths of the first doped region 131a and the second doped region 131b. In other words, the bottom of the third doped region 141a is higher than the bottom of the first doped region 131a, and the bottom of the fourth doped region 141b is higher than the bottom of the second doped region 131b. In some embodiments, since the thickness Ta of the first region 241a of the fourth oxide layer 241 is less than the thickness Tb of the second region 241b, the bottom of the fourth doped region 141b is higher than the bottom of the third doped region 141a.

In some embodiments, the third doped region 141a may be formed in the first portion of the second doped region 131b in the first region R1, and the bottom of the third doped region 141a may be in contact with the top of the first doped region 131a. The fourth doped region 141b may be formed in the second portion of the second doped region 131b in the second region R2, and the bottom of the fourth doped region 141b is higher than the second portion 131j of the first boundary 1311.

In some embodiments, an annealing process is performed after the third doped region 141a and the fourth doped region 141b are formed by the ion implantation process to diffuse the doping ions. In some embodiments, the third doped region 141a and the fourth doped region 141b are formed simultaneously and constitute a second doped block 141. As described above, the second doped block 141 has a border line (the second boundary) 1411 defining the region of the second doped block 141 in the epitaxial layer 112. The second boundary 1411 includes a third portion 141i which is the bottom surface of the third doped region 141a and a fourth portion 141j which is the bottom surface of the fourth doped region 141b. The third portion 141i may be coplanar with the top of the first doped region 131a. The fourth portion 141j may be higher than the second portion 131j. The fourth portion 141j may be higher than the third portion 141i or may be at the same depth as the third portion 141i.

In some embodiments, the range of the first doped region 131a and the third doped region 141a affects the SBR channel length L1 of the trench semiconductor structure 10, and the range of the second doped region 131b and the fourth doped region 141b affects the channel length L2 of the SGT MOSFET of the trench semiconductor structure 10 in the second region R2. The channel length L1 of the SBR and the channel length L2 of the SGT MOSFET may be adjusted independently according to the needs, for example, by adjusting the depth of the first doped region 131a, the thickness Ta of the first region 241a of the fourth oxide layer 241 and/or the thickness Tb of the second region 241b. In some embodiments, since the first doped region 131a is formed before the second doped region 131b, and the thickness Ta of the first region 241a of the fourth oxide layer 241 is less than the thickness Tb of the second region 241b, the channel length L1 of the subsequently formed SBR may be less than the channel length L2 of the SGT MOSFET.

The seventh doped region 142a is formed in the semiconductor material layer 11 and located between the first surface 11A and the fifth doped region 132a, and the eighth doped region 142b is formed in the semiconductor material layer 11 and located between the first surface 11A and the sixth doped region 132b. The seventh doped region 142a and the eighth doped region 142b have the first conductivity type.

The seventh doped region 142a and the eighth doped region 142b may be formed in the epitaxial layer 112 by diffusion or ion implantation from the first surface 11A, and ions are implanted into the first surface 11A along the vertical direction Z. The seventh doped region 142a is formed in the first region R1, and the eighth doped region 142b is formed in the third region R3. The depths of the seventh doped region 142a and the eighth doped region 142b are respectively less than the depths of the fifth doped region 132a and the sixth doped region 132b. In other words, the bottom of the seventh doped region 142a is higher than the bottom of the fifth doped region 132a, and the bottom of the eighth doped region 142b is higher than the bottom of the sixth doped region 132b. In some embodiments, since the thickness Tc of the third region 241c of the fourth oxide layer 241 is less than the thickness Td of the fourth region 241d, the bottom of the eighth doped region 142b is higher than the bottom of the seventh doped region 142a.

In some embodiments, the seventh doped region 142a may be formed in the first portion of the sixth doped region 132b in the first region R1, and the bottom of the seventh doped region 142a may be in contact with the top of the fifth doped region 132a. The eighth doped region 142b may be formed in the second portion of the sixth doped region 132b in the third region R3, and the bottom of the eighth doped region 142b is higher than the sixth portion 132j of the third boundary 1321.

In some embodiments, an annealing process is performed after the seventh doped region 142a and the eighth doped region 142b are formed by the ion implantation process to diffuse the doped ions. In some embodiments, the seventh doped region 142a and the eighth doped region 142b are formed simultaneously and constitute a fourth doped block 142. As described above, the fourth doped block 142 has a border line (the fourth boundary) 1421 defining the region of the fourth doped block 142 in the epitaxial layer 112. The fourth boundary 1421 includes a seventh portion 142i which is the bottom surface of the seventh doped region 142a and an eighth portion 142j which is the bottom surface of the eighth doped region 142b. The seventh portion 142i may be coplanar with the top of the fifth doped region 132a. The eighth portion 142j may be higher than the fifth portion 132i. The eighth portion 142j may be higher than the seventh portion 142i or may be at the same depth as the seventh portion 142i.

In some embodiments, the range of the fifth doped region 132a and the seventh doped region 142a affects the SBR channel length L3 of the trench semiconductor structure 10, and the range of the sixth doped region 132b and the eighth doped region 142b affects the channel length L4 of the SGT MOSFET of the trench semiconductor structure 10 in the third region R3. The channel length L3 of the SBR and the channel length L4 of the SGT MOSFET may be adjusted independently according to the needs, for example, by adjusting the depth of the fifth doped region 132a, the thickness Tc of the third region 241c of the fourth oxide layer 241, and/or the thickness Td of the fourth region 241d. In some embodiments, the fifth doped region 132a is formed before the sixth doped region 132b, the thickness Tc of the third region 241c of the fourth oxide layer 241 is less than the thickness Td of the fourth region 241d, and the channel length L3 of the subsequently formed SBR is less than the channel length L4 of the SGT MOSFET.

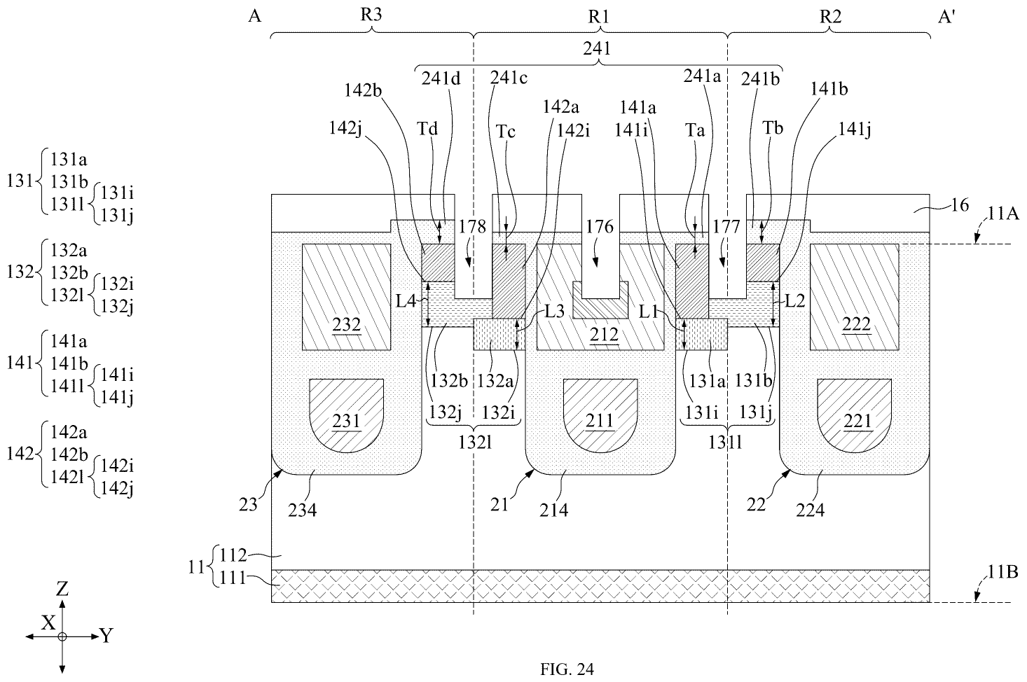

Referring to FIG. 24, the manufacturing method includes forming an interlayer dielectric layer 16 on the first surface 11A of the semiconductor material layer 11. The interlayer dielectric layer 16 covers the first trench structure 21, the second trench structure 22, the third trench structure 23, the third doped region 141a, the fourth doped region 141b, the seventh doped region 142a and the eighth doped region 142b. The manufacturing method includes forming the interlayer dielectric layer 16 on the fourth oxide layer 241. The interlayer dielectric layer 16 may be formed by thermal oxidation technology or other deposition processes.

The manufacturing method further includes partially removing the interlayer dielectric layer 16 and the fourth oxide layer 241, and partially removing the epitaxial layer 112 and the second electrode 212 to form a first opening 176, a second opening 177, and a third opening 178. The first opening 176, the second opening 177, and the third opening 178 may be formed by one or more etching processes. The first opening 176 is located on the electrode structure in the first region R1, exposing the second electrode 212. The first opening 176 extends into the second electrode 212 through the interlayer dielectric layer 16 and the fourth oxide layer 241.

The second opening 177 is located between the first trench structure 21 and the second trench structure 22, extends through the second doped block 141 and stops in the first doped block 131. The second opening 177 extends into the first doped block 131 through the interlayer dielectric layer 16, the fourth oxide layer 241 and the second doped block 141. The third opening 178 is located between the first trench structure 21 and the third trench junction 23, extends through the fourth doped block 142 and stops in the third doped block 132. The third opening 178 extends into the third doped block 132 through the interlayer dielectric layer 16, the fourth oxide layer 241 and the fourth doped block 142. In some embodiments, the second opening 177 is located at the junction of the first region R1 and the second region R2, and the third opening 178 is located at the junction of the first region R1 and the third region R3. The second opening 177 may have approximately the same width and approximately the same depth as the third opening 178. The width of the first opening 176 may be different from the width of the second opening 177 or the third opening 178. In some embodiments, the width of the first opening 176 is less than the width of the second opening 177 or the third opening 178. In some embodiments, the first opening 176, the second opening 177, and the third opening 178 may have approximately the same width and approximately the same depth.

In some embodiments, the second opening 177 passes through the second doped block 141 and the first doped block 131 and stops in the epitaxial layer 112. The second opening 177 may extend into the epitaxial layer 112 through the interlayer dielectric layer 16, the fourth oxide layer 241, the second doped block 141 and the first doped block 131. In some embodiments, the third opening 178 passes through the fourth doped block 142 and the third doped block 132 and stops in the epitaxial layer 112. The third opening 178 may extend into the epitaxial layer 112 through the interlayer dielectric layer 16, the fourth oxide layer 241, the fourth doped block 142, and the third doped block 132.

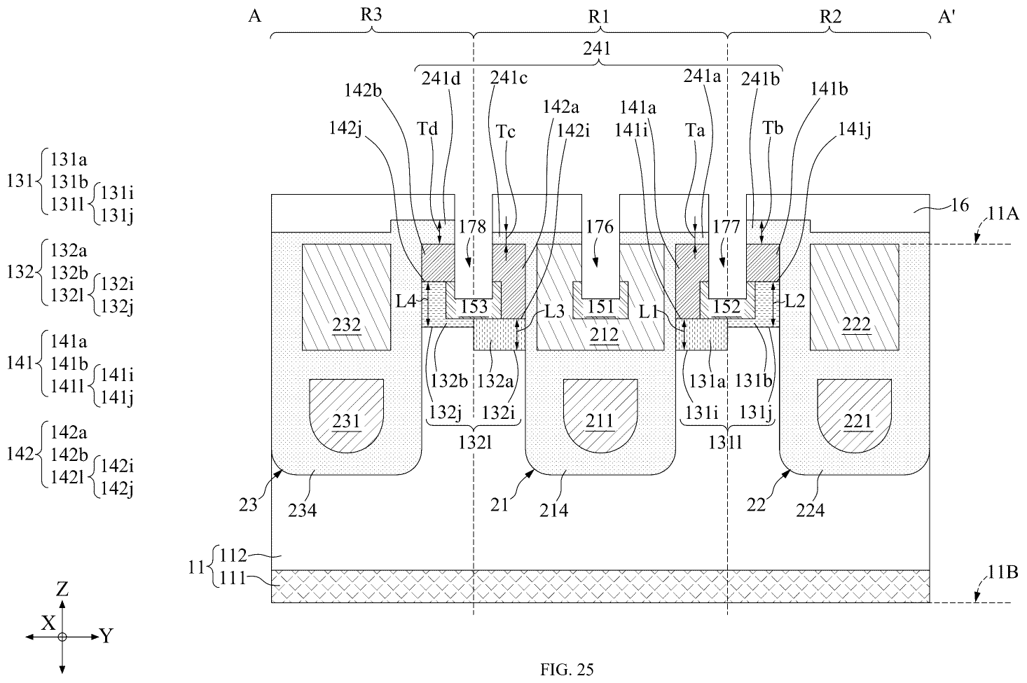

Referring to FIG. 25, the manufacturing method includes performing an ion implantation process on the second electrode 212 through the first opening 176, and performing an ion implantation process on the epitaxial layer 112 through the second opening 177 and the third opening 178, to form, respectively, a first heavily doped region 151 in the first region R1, a second heavily doped region 152 at the junction of the first region R1 and the second region R2, and a third heavily doped region 153 at the junction of the first region R1 and the third region R3. Ions are implanted into the second electrode 212 at the bottom of the first opening 176, and into the epitaxial layer 112 at the bottom of the second opening 177 and at the bottom of the third opening 178 along the vertical direction Z. The second heavily doped region 152 and the third heavily doped region 153 are respectively formed in the epitaxial layer 112 adjacent to the bottom of the second opening 177 and the bottom of the third opening 178. The second heavily doped region 152 is formed in the first doped block 131 and the second doped block 141. The third heavily doped region 153 is formed in the third doped block 132 and the fourth doped block 142. In some embodiments, an annealing process is performed after the ion implantation process is performed to form the first heavily doped region 151, the second heavily doped region 152, and the third heavily doped region 153 as shown in FIG. 25.

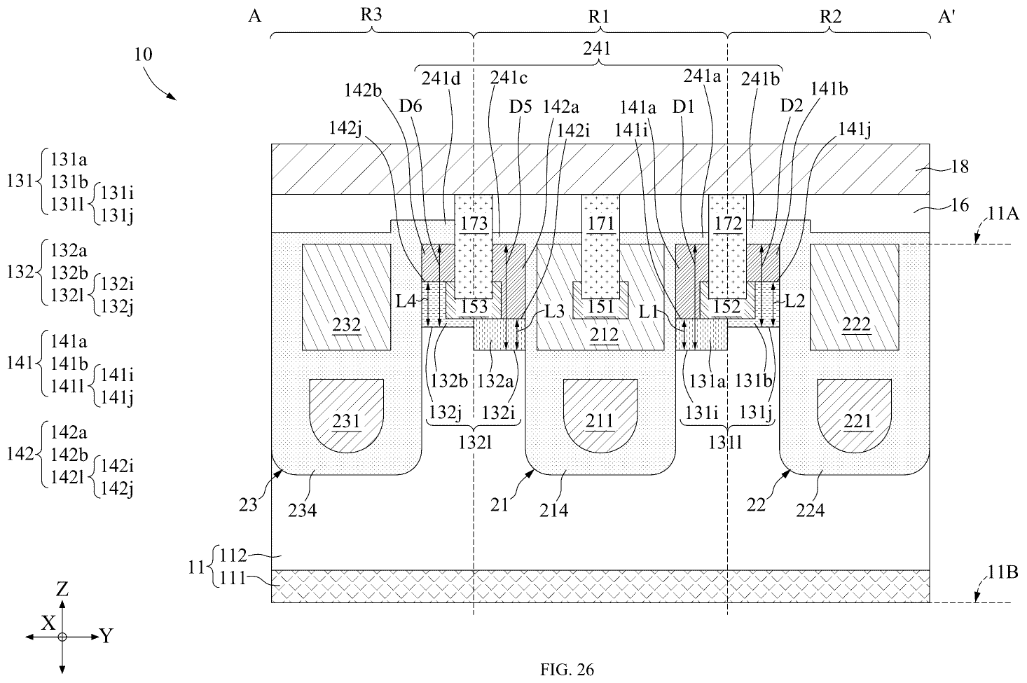

Referring to FIG. 26, the manufacturing method includes forming a first conductive plug 171 in the first opening 176, a second conductive plug 172 in the second opening 177, and a third conductive plug 173 in the third opening 178. The first conductive plug 171, the second conductive plug 172, and the third conductive plug 173 may be formed by electroplating or CVD, and the conductive material is filled into the first opening 176, the second opening 177, and the third opening 178, respectively. The first conductive plug 171, the second conductive plug 172, and the third conductive plug 173 may be formed simultaneously or separately, and the conductive material may include gold (Au), silver (Ag), copper (Cu), platinum (Pt), palladium (Pd), tungsten (W), titanium (Ti), tantalum (Ta), molybdenum (Mo), or other metals or alloys. In some embodiments, a planarization process may be optionally performed after electroplating or CVD. Therefore, in some embodiments, the top surfaces of the first conductive plug 171, the second conductive plug 172, and the third conductive plug 173 are flush with each other or are located at approximately the same level.

The configurations of the first conductive plug 171, the second conductive plug 172, and the third conductive plug 173 may be defined by the configurations of the first opening 176, the second opening 177 and the third opening 178, respectively, and thus may have the same configurations as the first opening 176, the second opening 177 and the third opening 178, respectively. The first conductive plug 171 contacts the second electrode 212 and the first heavily doped region 151 in the first region R1, the second conductive plug 172 contacts the first doped block 131, the second doped block 141 and the second heavily doped region 152, and the third conductive plug 173 contacts the third doped block 132, the fourth doped block 142 and the third heavily doped region 153.

The manufacturing method includes forming a metal layer 18 on the interlayer dielectric layer 16 and forming a trench semiconductor structure 10. After the metal layer 18 is formed, the trench semiconductor structure 10 is formed by the manufacturing method. The metal layer 18 may be formed by electroplating or CVD, and the metal layer 18 may be patterned according to electrical properties and operational requirements. The material of the metal layer 18 may include copper (Cu), gold (Au), silver (Ag), aluminum (Al), nickel (Ni), titanium (Ti), tungsten (W), tin (Sn) or other metals or alloys. In some embodiments, the metal layer 18 is defined as a plurality of metal wires using an etching process. In some embodiments, the metal layer 18 contacts the interlayer dielectric layer 16 and is electrically connected to the first conductive plug 171, the second conductive plug 172, and the third conductive plug 173. The first conductive plug 171, the second conductive plug 172, and the third conductive plug 173 extend from the metal layer 18 along the vertical direction Z. The first conductive plug 171 is formed between the first trench structure 21 and the metal layer 18, the second conductive plug 172 is formed between the first doped block 131 and the metal layer 18, and the third conductive plug 173 is formed between the third doped block 132 and the metal layer 18.

The trench semiconductor structure 10 of FIG. 26 formed through the above steps may be substantially the same as one of the semiconductor structures 10 shown in FIG. 1, FIG. 2, FIG. 4, and FIG. 5. In the trench semiconductor structure 10, the distance D1 between the bottom surface of the first doped region 131a and the first surface 11A is different from the distance D2 between the bottom surface of the second doped region 131b and the first surface 11A, and the distance D5 between the bottom surface of the fifth doped region 132a and the first surface 11A is different from the distance D6 between the bottom surface of the sixth doped region 132b and the first surface 11A.

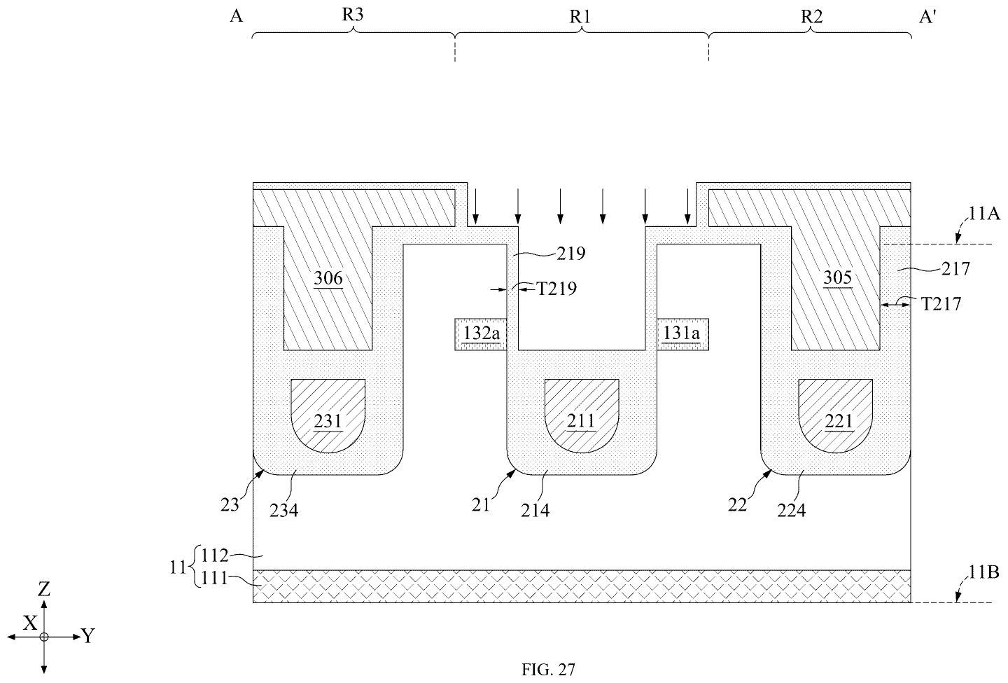

FIG. 27 to FIG. 30 show another example of stages in a manufacturing method of a trench semiconductor structure according to embodiments of the present disclosure. As described above with respect to FIG. 18, FIG. 27 is based on the trench semiconductor structure after the steps shown in FIG. 7 to FIG. 17 are performed. Similar to the step performed in FIG. 18, referring to FIG. 27, the manufacturing method includes forming the fourth in-trench oxide layer 219 in the first region R1, the second region R2, and the third region R3, and forming the first doped region 131a and the fifth doped region 132a in the epitaxial layer 112 in the first region R1. In some embodiments, the thickness T219 of the fourth in-trench oxide layer 219 may be substantially the same as the thickness T217 of the second in-trench oxide layer 217. In some embodiments, as shown in FIG. 27, the thickness of the fourth in-trench oxide layer 219 formed on the first surface 11A may be the same as the thickness of the second in-trench oxide layer 217 formed on the first surface 11A.

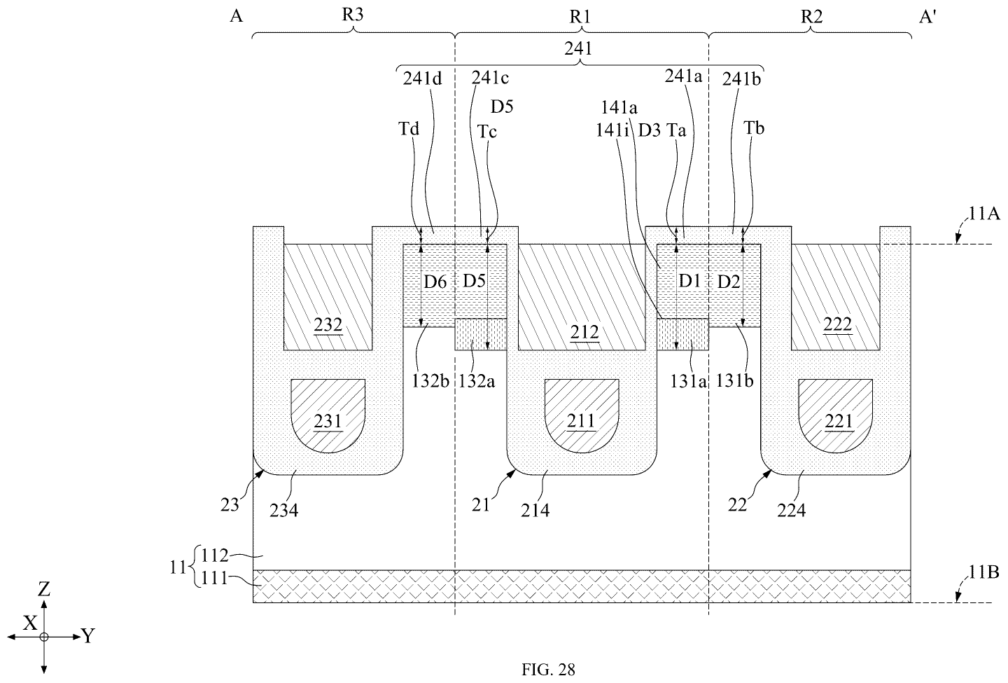

Based on the trench semiconductor structure in FIG. 27, in some embodiments, referring to FIG. 28, the manufacturing method includes forming the second electrode 212, the first gate 222, and the second gate 232, and forming the fourth in-trench oxide layer 219 on the first surface 11A into a fourth oxide layer 241, which may be similar to those described above with respect to FIGS. 19-21. In some embodiments, the manufacturing method includes planarizing the fourth in-trench oxide layer 219 or the fourth oxide layer 241, such that the thickness Ta of the first region 241a of the fourth oxide layer 241 is the same as the thickness Tb of the second region 241b, and the thickness Tc of the third region 241c is the same as the thickness Td of the fourth region 241d. The fourth oxide layer 241 may be polished, for example, by a chemical-mechanical polishing (CMP) process.

The manufacturing method further includes forming the second doped region 131b between the fourth oxide layer 241 and the first doped region 131a, and forming the sixth doped region 132b between the fourth oxide layer 241 and the fifth doped region 132a. The second doped region 131b and the sixth doped region 132b may be formed similarly to those described above with respect to FIG. 22.

In some embodiments, the distance D1 between the bottom surface of the first doped region 131a and the first surface 11A is greater than the distance D2 between the bottom surface of the second doped region 131b and the first surface 11A. The distance D5 between the bottom surface of the fifth doped region 132a and the first surface 11A is greater than the distance D6 between the bottom surface of the sixth doped region 132b and the first surface 11A. In some embodiments, the distance D1 may be substantially the same as the distance D2, and the distance D5 may be substantially the same as the distance D6.

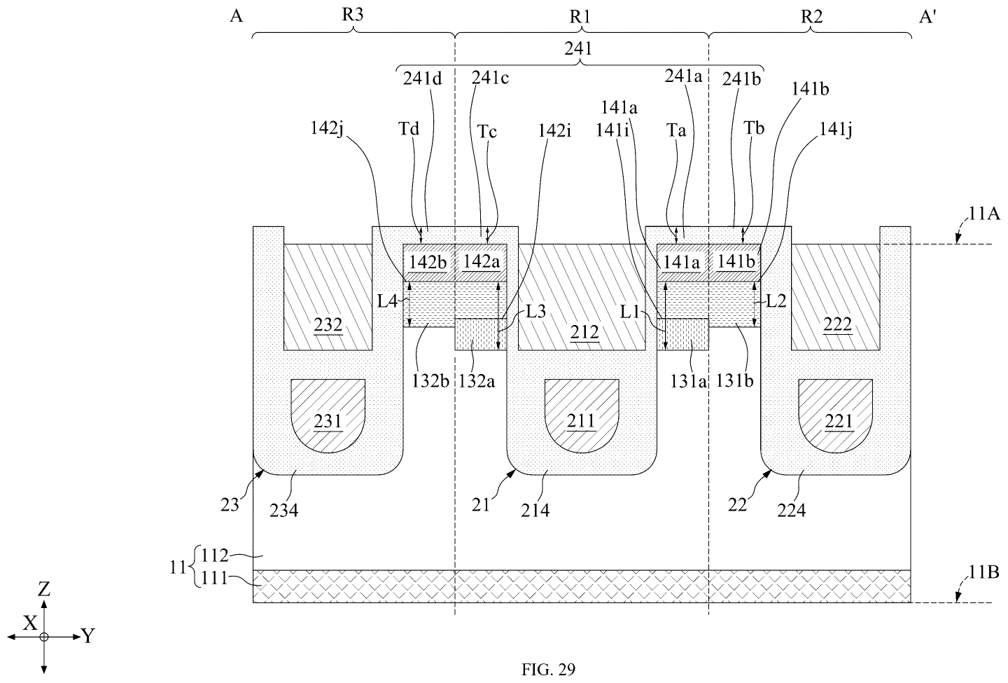

In some embodiments, referring to FIG. 29, the manufacturing method includes forming the third doped region 141a and the fourth doped region 141b in the semiconductor material layer 11 between the first trench structure 21 and the second trench structure 22, and forming the seventh doped region 142a and the eighth doped region 142b in the semiconductor material layer 11 between the first trench structure 21 and the third trench structure 23. The third doped region 141a, the fourth doped region 141b, the seventh doped region 142a and the eighth doped region 142b may be formed similarly to those described above with respect to FIG. 23. However, since the thickness Ta of the first region 241a, the thickness Tb of the second region 241b, the thickness Tc of the third region 241c and the thickness Td of the fourth region 241d of the fourth oxide layer 241 are substantially the same in this example, the bottom of the third doped region 141a is coplanar with the bottom of the fourth doped region 141b, and the bottom of the seventh doped region 142a is coplanar with the bottom of the eighth doped region 142b. In some embodiments, the bottom of the third doped region 141a, the fourth doped region 141b, the seventh doped region 142a and the eighth doped region 142b may be coplanar with one another. In some embodiments, since the first doped region 131a is formed before the second doped region 131b, and the thickness Ta of the first region 241a of the fourth oxide layer 241 is substantially the same as the thickness Tb of the second region 241b, the channel length L1 of the SBR to be formed subsequently is greater than the channel length L2 of the SGT MOSFET. Similarly, since the fifth doped region 132a is formed before the sixth doped region 132b, and the thickness Tc of the third region 241c of the fourth oxide layer 241 is substantially the same as the thickness Td of the fourth region 241d, the channel length L3 of the SBR to be formed subsequently is greater than the channel length L4 of the SGT MOSFET.

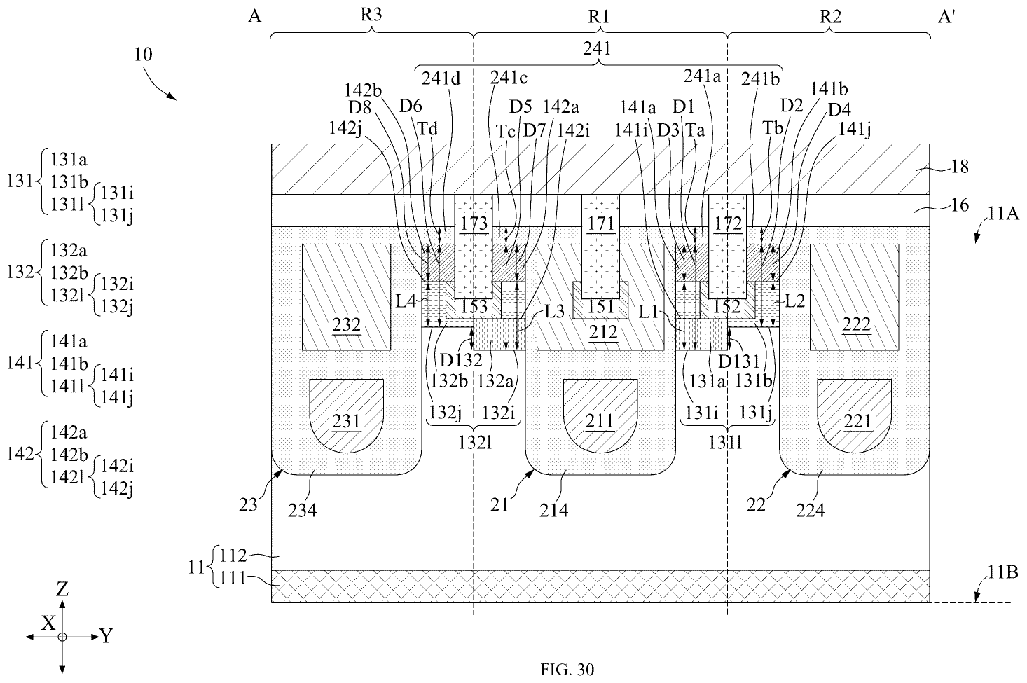

In some embodiments, referring to FIG. 30, the manufacturing method includes forming the interlayer dielectric layer 16 on the fourth oxide layer 241, forming the first heavily doped region 151, the second heavily doped region 152, and the third heavily doped region 153, forming the first conductive plug 171, the second conductive plug 172, and the third conductive plug 173, and forming the metal layer 18 on the interlayer dielectric layer 16. The trench semiconductor structure 10 formed by the above steps may be substantially the same as the semiconductor structure 10 shown in FIG. 3 or FIG. 6.

The trench semiconductor structures 10 of the present disclosure integrate the SBR and the SGT MOSFETs, where the channel lengths L1 and L3 of the SBR and the channel lengths L2 and L4 of the SGT MOSFETs may be adjusted independently according to requirements, for example, by controlling the positions of the first doped region 131a and the fifth doped region 132a, and/or by changing the thickness of each region of the fourth oxide layer 241 to adjust the relative position of each doped region. This enables the trench semiconductor structures 10 to have the flexibility to adjust the channel length of the SBR and the channel lengths of the SGT MOSFETs respectively.

Further embodiments are provided in the following.

In one embodiment, a trench semiconductor structure includes: a semiconductor material layer having a first surface and a second surface opposite to the first surface, wherein the semiconductor material layer has a first conductivity type; a first trench structure extending from the first surface toward the second surface, wherein the first trench structure comprises a first electrode, a second electrode located above the first electrode, and a first oxide layer surrounding the first electrode and the second electrode and separating them from each other; a second trench structure extending from the first surface toward the second surface and disposed adjacent to the first trench structure, wherein the second trench structure comprises a first gate, a third electrode located below the first gate, and a second oxide layer surrounding the third electrode and the first gate and separating them from each other; a first doped block located in the semiconductor material layer, away from the first surface, and between the first trench structure and the second trench structure, wherein the first doped block has a second conductivity type, and a first boundary defining the first doped block in the semiconductor material layer includes a first portion and a second portion; and a second doped block, located between the first surface and the first doped block, wherein the second doped block has the first conductivity type, and wherein the first portion of the first boundary is adjacent to the first trench structure, the second portion of the first boundary is adjacent to the second trench structure, and a distance between the first portion and the first surface is different from a distance between the second portion and the first surface.

Optionally, in the previous embodiment, the trench semiconductor structure further comprises: a fourth oxide layer located on the first surface of the semiconductor material layer and between an interlayer dielectric layer and the second doped block, wherein the fourth oxide layer includes a first region and a second region, the first region is located above the first portion, the second region is located above the second portion, a thickness of the first region is the same as or different from a thickness of the second region.

Optionally, in any of the previous embodiments, the distance between the first portion and the first surface is greater than the distance between the second portion and the first surface.

Optionally, in any of the previous embodiments, the distance between the first portion and the first surface is substantially the same as the distance between the second portion and the first surface.

Optionally, in any of the previous embodiments, a second boundary defines the second doped block between the second doped block and the first doped block, the second boundary comprises a third portion and a fourth portion, the third portion is adjacent to the first trench structure, the fourth portion is adjacent to the second trench structure, and a distance between the third portion and the first surface is the same as or different from a distance between the fourth portion and the first surface.

Optionally, in any of the previous embodiments, the distance between the third portion of the second boundary and the first surface is greater than the distance between the fourth portion of the second boundary and the first surface.

Optionally, in any of the previous embodiments, the distance between the first portion of the first boundary and the first surface is greater than the distance between the third portion of the second boundary and the first surface, and the first portion overlaps with the third portion when viewed from a top view.

Optionally, in any of the previous embodiments, the distance between the second portion of the first boundary and the first surface is greater than the distance between the fourth portion of the second boundary and the first surface, and the second portion overlaps with the fourth portion when viewed from a top view.

Optionally, in any of the previous embodiments, a doping concentration of a first doped block between the first portion of the first boundary and the third portion of the second boundary is different from a doping concentration of a first doped block between the second portion of the first boundary and the fourth portion of the second boundary.

Optionally, in any of the previous embodiments, the trench semiconductor structure further comprises: a third trench structure extending from the first surface toward the second surface and disposed adjacent to the first trench structure, wherein the third trench structure comprises a fourth electrode, a second gate located above the fourth electrode, and a third oxide layer surrounding the fourth electrode and the second gate and separating them from each other; and a third doped region located in the semiconductor material layer, away from the first surface, and between the first trench structure and the third trench structure, wherein the third doped region has the second conductivity type, and a third boundary defining the third doped region in the semiconductor material layer includes a fifth portion and a sixth portion, the fifth portion of the third boundary is adjacent to the first trench structure, and the sixth portion of the third boundary is adjacent to the third trench structure.

Optionally, in any of the previous embodiments, a distance between the fifth portion and the first surface is different from a distance between the sixth portion and the first surface.

Optionally, in any of the previous embodiments, the trench semiconductor structure further comprises: an interlayer dielectric layer, located on the first surface of the semiconductor material layer and covering the first trench structure, the second trench structure, the first doped block, and the second doped block; and a metal layer located on the interlayer dielectric layer.

Optionally, in any of the previous embodiments, the trench semiconductor structure further comprises: a first conductive plug electrically connected to the second electrode and the metal layer; a first heavily doped region, surrounded by the second electrode and having the second conductivity type; and a second conductive plug electrically connects the heavily doped region and the metal layer; and a second heavily doped region surrounded by the first doped block and the second doped block and having the second conductivity type.

Optionally, in any of the previous embodiments, the second conductive plug extends through the first heavily doped region and the first doped region.

Optionally, in any of the previous embodiments, the first oxide layer surrounding the first electrode has a first thickness, the first oxide layer surrounding the second electrode has a second thickness, and the first thickness is greater than the second thickness.

In another embodiment, a trench semiconductor structure includes: a semiconductor material layer having a first surface and a second surface opposite to the first surface, wherein the semiconductor material layer has a first conductivity type; a first trench structure extending from the first surface toward the second surface, wherein the first trench structure includes a first electrode, a second electrode located above the first electrode, and a first oxide layer surrounding the first electrode and the second electrode and separating them from each other; a second trench structure extending from the first surface toward the second surface and disposed adjacent to the first trench structure, wherein the second trench structure comprises a first gate, a third electrode located below the first gate, and a second oxide layer surrounding the third electrode and the first gate and separating them from each other; a first doped region, located in the semiconductor material layer, away from the first surface, and between the first trench structure and the second trench structure, wherein the first doped region has a second conductivity type and contacts the first oxide layer; and a second doped region, located in the semiconductor material layer, away from the first surface, and between the first doped region and the second trench structure, wherein the second doped region has a second conductivity type and contacts the second oxide layer; and wherein a length of the first doped region is different from a length of the second doped region.

Optionally, in any of the previous embodiments, the trench semiconductor structure further includes: a third doped region, located in the semiconductor material layer and between the first surface and the first doped region, wherein the third doped region has the first conductivity type; and a fourth doped region, located in the semiconductor material layer and between the first surface and the second doped region, wherein the fourth doped region has the first conductivity type.

Optionally, in any of the previous embodiments, when a distance between the first doped region and the first surface is less than a distance between the second doped region and the first surface, a distance between the third doped region and the first surface is greater than or equal to a distance between the fourth doped region and the first surface, and when the distance between the first doped region and the first surface is greater than the distance between the second doped region and the first surface, the distance between the third doped region and the first surface is greater than or equal to the distance between the fourth doped region and the first surface.

Optionally, in any of the previous embodiments, a bottom surface of the third doped region is coplanar with a bottom surface of the fourth doped region.

Optionally, in any of the previous embodiments, a bottom surface of the first doped region or a bottom surface of the second doped region is coplanar with a bottom surface of the second electrode.

Optionally, in any of the previous embodiments, the trench semiconductor structure further includes: a fourth oxide layer located on the first surface of the semiconductor material layer, wherein the fourth oxide layer includes a first region and a second region, the first region is located above the first doped region, the second region is located above the second doped region, and a top surface of the first region is coplanar with a top surface of the second region.

Optionally, in any of the previous embodiments, the first doped region is a super-barrier-rectifier (SBR) channel, and the second doped region is a metal oxide semiconductor field effect transistor (MOSFET) channel.

In another embodiment, a manufacturing method of a trench semiconductor structure includes: forming a first trench and a second trench in a semiconductor material layer, wherein the semiconductor material layer has a first conductivity type, and the first trench and the second trench extend from a first surface toward a second surface; forming a first electrode and a first oxide layer in the first trench, wherein the first oxide layer surrounds the first electrode and conforms to the first trench; forming a third electrode, a first gate and a second oxide layer in the second trench, wherein the second oxide layer surrounds the third electrode and the first gate and conforms to the second trench, and the third electrode, the first gate and the second oxide layer form a second trench structure; forming a first doped region in the semiconductor material layer, away from the first surface, and between the first trench and the second trench, wherein the first doped region is in contact with the first oxide layer; forming a second electrode in the first trench, wherein at least a portion of the first oxide layer is between the second electrode and the first doped region, and the first electrode, the second electrode and the first oxide layer form a first trench structure; and forming a second doped region in the semiconductor material layer, away from the first surface, and between the first doped region and the second trench, wherein the second doped region has a second conductivity type and is in contact with the first doped region and the second oxide layer, wherein a distance between a bottom surface of the first doped region and the first surface is different from a distance between a bottom surface of the second doped region and the first surface.

Optionally, in the previous embodiment, the second trench structure is formed before the first trench structure.

Optionally, in any of the previous embodiments, the distance between the bottom surface of the first doped region and the first surface is greater than the distance between the bottom surface of the second doped region and the first surface.

Optionally, in any of the previous embodiments, the manufacturing method further includes: forming a third doped region in the semiconductor material layer and between the first surface and the first doped region, wherein the third doped region has the first conductivity type; forming a fourth doped region in the semiconductor material layer and located in the semiconductor material layer, and between the first surface and the second doped region, wherein the fourth doped region has the first conductivity type; forming an interlayer dielectric layer on the first surface of the semiconductor material layer, wherein the interlayer dielectric layer covers the first trench structure, the second trench structure, the third doped region, and the fourth doped region; and forming a metal layer on the interlayer dielectric layer.

Optionally, in any of the previous embodiments, the third doped region and the fourth doped region are formed simultaneously.

Optionally, in any of the previous embodiments, the manufacturing method further includes: forming a first conductive plug between the first trench structure and the metal layer, wherein the first conductive plug extends from the metal layer and is electrically connected to the second electrode; and forming a second conductive plug between the second doped region and the metal layer, wherein the second conductive plug extends from the metal layer, extends through the third doped region and the fourth doped region, and is electrically connected to the first doped region.

Optionally, in any of the previous embodiments, the first conductive plug and the second conductive plug are formed simultaneously.

Optionally, in any of the previous embodiments, the manufacturing method further includes: forming a third trench in the semiconductor material, wherein the third trench extends from the first surface toward the second surface and is disposed adjacent to the first trench; and forming a fourth electrode, a second gate and a third oxide layer in the third trench, wherein the third oxide layer surrounds the fourth electrode and the second gate and separates them from each other, and the third oxide layer is conformal to the third trench; and wherein the fourth electrode, the second gate and the third oxide layer form a third trench structure, and the first trench structure is located between the second trench structure and the third trench structure.

Optionally, in any of the previous embodiments, the third trench structure is formed simultaneously with the second trench structure.

Optionally, in any of the previous embodiments, the manufacturing method further includes: before forming the second doped region, forming a fourth oxide layer on the first surface of the semiconductor material layer and between the first trench structure and the second trench structure, wherein the fourth oxide layer includes a first region and a second region, the first region is located above the first doped region, and the second region is located above the second doped region, and a thickness of the first region is the same as or different from a thickness of the second region.

Optionally, in any of the previous embodiments, when the thickness of the second region is greater than the thickness of the first region, a distance between the third doped region and the first surface is greater than a distance between the fourth doped region and the first surface.

Optionally, in any of the previous embodiments, the manufacturing method further includes: planarizing the fourth oxide layer such that the thickness of the first region is the same as the thickness of the second region.

According to the structures and processes of embodiments of the present disclosure described above, under the same purpose and concept, the steps in the above processes may be adjusted or replaced in sequence to achieve the same or similar semiconductor structures.

In this disclosure, for description convenience, spatially relative terms such as “below”, “under”, “lower”, “above”, “upper”, “left side”, “right side”, and so on, may be used to describe the relationship of one component or feature with another one or more components or features, as shown in the accompanying drawings. The spatially relative terms are not only used to depict the orientations in the accompanying drawings, but also intended to encompass different orientations of a device in use or operation. A device may be oriented in other ways (rotated 90 degrees or in other orientations), and the spatially relative terms used herein may be interpreted in a corresponding way similarly. It should be understood that when a component is referred to as being “connected” or “coupled” to another component, it can be directly connected or coupled to another component or an intervening component may be present.

As used herein, the terms “approximately”, “basically”, “substantially” and “about” are used to describe and account for small variations. When used in conjunction with an event or instance, the terms may refer to an embodiment of exact occurrence of an event or instance as well as an embodiment where the event or instance is close to occurrence. As used herein with respect to a given value or range, the term “about” generally means being within ±10%, ±5%, ±1%, or ±0.5% of the given value or range. A range herein may be referred to as being from one endpoint to the other or as being between two endpoints. All ranges disclosed herein are inclusive of the endpoints unless otherwise indicated. The term “substantially coplanar” may mean that the difference of positions of two surfaces with reference to the same plane is within a few micrometers (μm), e.g., within 10 μm, within 5 μm, within 1 μm, or within 0.5 μm. When values or characteristics are referred to as being “substantially” the same, the term may refer to a value that is within ±10%, ±5%, ±1%, or ±0.5% of the mean of the values.

The foregoing has outlined features of some embodiments and detailed aspects of present disclosure. The embodiments described in the present disclosure may be readily used as a basis for designing or modifying other processes and structures in order to carry out the same or similar purposes and/or to achieve the same or similar advantages of the embodiments presented herein. Such equivalent constructions do not depart from the spirit and scope of the present disclosure, and various changes, substitutions, and alterations can be made without departing from the spirit and scope of the present disclosure.

Although the description has been described in detail, it should be understood that various changes, substitutions and alterations can be made without departing from the spirit and scope of this disclosure as defined by the appended claims. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, which may perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, or steps.

What is claimed:

1. A trench semiconductor structure, comprising:
a semiconductor material layer of a first conductivity type, the semiconductor material layer having a first surface and a second surface opposite to the first surface;
a first trench structure extending from the first surface toward the second surface, wherein the first trench structure comprises a first electrode, a second electrode located above the first electrode, and a first oxide layer surrounding and separating the first electrode and the second electrode;
a second trench structure extending from the first surface toward the second surface, wherein the second trench structure comprises a first gate, a third electrode located below the first gate, and a second oxide layer surrounding and separating the third electrode and the first gate;
a first doped region of a second conductivity type in the semiconductor material layer, away from the first surface, and between the first trench structure and the second trench structure, wherein the first doped region has a first boundary between the first doped region and the semiconductor material layer, and the first boundary includes a first portion and a second portion; and
a second doped region of the first conductivity type between the first surface and the first doped region.

2. The trench semiconductor structure according to claim 1, further comprising:
a fourth oxide layer on the first surface of the semiconductor material layer, wherein the fourth oxide layer includes a first region located above the first portion of the first boundary and a second region located above the second portion of the first boundary.

3. The trench semiconductor structure according to claim 1, wherein a distance between the first portion of the first boundary and the first surface is greater than a distance between the second portion of the first boundary and the first surface.

4. The trench semiconductor structure according to claim 1, wherein a distance between the first portion of the first boundary and the first surface is substantially same as a distance between the second portion of the first boundary and the first surface.

5. The trench semiconductor structure according to claim 1, wherein the second doped region has a second boundary between the second doped region and the first doped region, the second boundary comprises a third portion and a fourth portion, and a distance between the third portion and the first surface is greater than or equal to a distance between the fourth portion and the first surface.

6. The trench semiconductor structure according to claim 5, wherein a distance between the first portion of the first boundary and the first surface is greater than the distance between the third portion of the second boundary and the first surface, and the first portion overlaps with the third portion in a top view of the trench semiconductor structure.

7. The trench semiconductor structure according to claim 5, wherein a distance between the second portion of the first boundary and the first surface is greater than the distance between the fourth portion of the second boundary and the first surface, and the second portion overlaps with the fourth portion in a top view of the trench semiconductor structure.

8. The trench semiconductor structure of claim 5, wherein a doping concentration of a portion of the first doped region located between the first portion of the first boundary and the third portion of the second boundary is different from a doping concentration of a portion of the first doped region located between the second portion of the first boundary and the fourth portion of the second boundary.

9. The trench semiconductor structure according to claim 1, further comprising:
a third trench structure extending from the first surface toward the second surface, wherein the third trench structure comprises a fourth electrode, a second gate located above the fourth electrode, and a third oxide layer surrounding and separating the fourth electrode and the second gate; and
a third doped region of the second conductivity type in the semiconductor material layer, away from the first surface, and between the first trench structure and the third trench structure.

10. The trench semiconductor structure according to claim 9, wherein the third doped region has a third boundary between the third doped region and the semiconductor material layer, the third boundary includes a fifth portion and a sixth portion, and a distance between the fifth portion and the first surface is different from a distance between the sixth portion and the first surface.

11. A trench semiconductor structure, comprising:
a semiconductor material layer of a first conductivity type having a first surface and a second surface opposite to the first surface;
a first trench structure extending from the first surface toward the second surface, wherein the first trench structure includes a first electrode, a second electrode located above the first electrode, and a first oxide layer surrounding and separating the first electrode and the second electrode;
a second trench structure extending from the first surface toward the second surface, wherein the second trench structure comprises a first gate, a third electrode located below the first gate, and a second oxide layer surrounding and separating the third electrode and the first gate;
a first doped region of a second conductivity type, located in the semiconductor material layer in contact with the first oxide layer, away from the first surface, and between the first trench structure and the second trench structure; and
a second doped region of the second conductivity type, located in the semiconductor material layer, away from the first surface, between the first doped region and the second trench structure, and in contact with the second oxide layer; and
wherein a length of the first doped region is different from a length of the second doped region.

12. The trench semiconductor structure according to claim 11, further comprising:
a third doped region of the first conductivity type, located in the semiconductor material layer and between the first surface and the first doped region; and
a fourth doped region of the first conductivity type, located in the semiconductor material layer and between the first surface and the second doped region.

13. The trench semiconductor structure according to claim 12, wherein,
a distance between the first doped region and the first surface is less than a distance between the second doped region and the first surface, and a distance between the third doped region and the first surface is greater than or equal to a distance between the fourth doped region and the first surface; or
the distance between the first doped region and the first surface is greater than the distance between the second doped region and the first surface, and the distance between the third doped region and the first surface is greater than or equal to the distance between the fourth doped region and the first surface.

14. The trench semiconductor structure according to claim 12, wherein a bottom surface of the third doped region is coplanar with a bottom surface of the fourth doped region.

15. The trench semiconductor structure according to claim 11, wherein a bottom surface of the first doped region or a bottom surface of the second doped region is coplanar with a bottom surface of the second electrode.

16. The trench semiconductor structure according to claim 11, further comprising:
a fourth oxide layer located on the first surface of the semiconductor material layer, wherein the fourth oxide layer includes a first region and a second region, the first region is located above the first doped region, the second region is located above the second doped region, and a top surface of the first region is coplanar with a top surface of the second region.

17. The trench semiconductor structure according to claim 11, wherein the first doped region is a super barrier rectifier (SBR) channel, and the second doped region is a metal oxide semiconductor field effect transistor (MOSFET) channel.

18. A method of manufacturing a trench semiconductor structure comprising:
forming a first trench and a second trench in a semiconductor material layer of a first conductivity type, wherein the first trench and the second trench extend from a first surface of the semiconductor material layer toward a second surface of the semiconductor material layer;
forming, in the first trench, a first electrode, a second electrode, and a first oxide layer surrounding and separating the first electrode and the a second electrode, the first electrode, the second electrode and the first oxide layer forming a first trench structure;
forming, in the second trench, a third electrode, a first gate, and a second oxide layer surrounding and separating the third electrode and the first gate, the third electrode, the first gate and the second oxide layer forming a second trench structure;
forming a first doped region in the semiconductor material layer, away from the first surface, and between the first trench and the second trench, wherein at least a portion of the first oxide layer is between the second electrode and the first doped region, and the first doped region is in contact with the first oxide layer; and
forming a second doped region in the semiconductor material layer, away from the first surface, and between the first doped region and the second trench, wherein the second doped region is in contact with the first doped region and the second oxide layer; and
wherein a distance between a bottom surface of the first doped region and the first surface is different from a distance between a bottom surface of the second doped region and the first surface.

19. The method according to claim 18, further comprising:
forming a third doped region of the first conductivity type in the semiconductor material layer and between the first surface and the first doped region;
forming a fourth doped region of the first conductivity type in the semiconductor material layer and between the first surface and the second doped region.

20. The method according to claim 18, further comprising:
forming a fourth oxide layer on the first surface of the semiconductor material layer and between the first trench structure and the second trench structure, wherein the fourth oxide layer includes a first region and a second region, the first region is located above the first doped region, and the second region is located above the second doped region.
